(19) United States
(12) Patent Application Publication
(10) Pub. No.: US 2009/0281677 A1
(43) Pub. Date: Nov. 12, 2009

(54) SYSTEMS AND METHODS FOR ASSESSING AND OPTIMIZING ENERGY USE AND ENVIRONMENTAL IMPACT

(75) Inventors: George Botich, Corona, CA (US); Shiva Subramanya, Irvine, CA (US); Mark R. Pieter, Irvine, CA (US); Ricky Chang, Irvine, CA (US); Sarathy Narasimhan, Costa Mesa, CA (US)

Correspondence Address: KNOBBE MARTENS OLSON & BEAR LLP, 2040 MAIN STREET, FOURTEENTH FLOOR, IRVINE, CA, 92614, US

(73) Assignee: ENERGY AND POWER SOLUTIONS, INC., Costa Mesa, CA (US)

(21) Appl. No.: 12/464,839

(22) Filed: May 12, 2009

Related U.S. Application Data
(60) Provisional application No. 61/052,607, filed on May 12, 2008.
(60) Provisional application No. 61/053,645, filed on May 15, 2008.

(51) Int. Cl. G06F 1/32; G01R 21/00; G06F 19/00; G08B 21/00; G06F 17/00; G06F 1/26

(52) U.S. Cl. 700/295; 702/62; 702/23; 340/540; 705/400

(57) ABSTRACT

Systems and methods for assessing and optimizing energy use and environmental impact can be designed to receive energy consumption and emission data from one or more energy consumption sources of a facility over a network. The data can be transformed into a database format that can be processed and analyzed. The data can be validated according to predefined validation rules. The data can be aggregated according to predefined time intervals and stored in memory. The data can be used to generate a report to a user, for example, via a user interface.

### PRIORITY INFORMATION

This application claims priority benefit under 35 U.S.C. § 119(e) to the following United States provisional patent applications, each of which is hereby incorporated herein by reference in its entirety to be considered part of this specification:

U.S. Provisional Patent Application No. 61/052,607, filed May 12, 2008, and entitled “SYSTEMS AND METHODS FOR ASSESSING ENERGY USE AND ENVIRONMENTAL IMPACT”; and

U.S. Provisional Patent Application No. 61/053,645, filed May 15, 2008, and entitled “SYSTEMS AND METHODS FOR OPTIMIZING ENERGY USE AND ENVIRONMENTAL IMPACT.”

### BACKGROUND OF THE INVENTIONS

1. Field of the Inventions

The present inventions relate to controller area networks, and more particularly, network monitoring and control systems used for the optimization of energy consumption and waste emissions.

2. Description of the Related Art

Due to the increasing costs of energy usage, worldwide concern regarding greenhouse gases, such as carbon dioxide, nitrogen oxide, and sulfur dioxide and other energy and emissions concerns, the search for new solutions to these issues has experienced a new surge. For example, many businesses such as those including large manufacturing facilities, are seeking out ways to both reduce energy costs and reduce the greenhouse gas emissions produced by their manufacturing and production facilities.

In order to reduce energy costs, some facility managers are monitoring energy consumption and greenhouse gas emissions data in order to find areas in which the company can be more efficient. The use of existing systems, some of which include data loggers refreshed on a monthly basis, can result in long lead times and high labor costs involved in monitoring the data and in presenting the data in a format useful for management personnel to understand and respond to.

### SUMMARY

An aspect of at least one of the embodiments disclosed herein includes the realization that network communication techniques can be used to enhance and simplify procedures for collecting data across controller area networks so that the users of such data, such as facilities managers, can more quickly and accurately identify potential areas for improvement such as reductions in energy consumption or waste emissions.

Thus, in accordance with an embodiment, a method for optimizing power consumption of manufacturing facilities can comprise receiving a plurality of energy consumption and emission data from one or more energy consuming devices operating in a facility over a network and transforming the plurality of data into a format that can be processed. The method can also include validating the plurality of data, aggregating the plurality of data at a defined interval, performing one or more analyses on the plurality of data using one or more computing devices, and storing the results of the one or more analyses in computer storage.

In accordance with another embodiment, a system for optimizing power consumption of manufacturing or production facilities can comprise one or more energy consumption sources, a data acquisition device configured to receive data from the one or more energy consumption sources, and a computing device configured to poll the data acquisition device at a defined interval and receive sensor data corresponding to the defined interval, the computing device being configured to transform the data into a format that can be processed. The system can also include a remote server in communication with the computing device, the remote server configured to receive the formatted data corresponding to the defined interval over a network, the remote server comprising a computer memory that stores instructions for creating reports that describe energy usage and emissions output of the one or more energy consumption sensors and at least one processor that executes the stored instructions.

In accordance with another embodiment, a method for monitoring energy consumption or waste emissions of a facility can comprise monitoring a plurality of data representing energy consumption or waste emissions of a facility, identifying a subset of the plurality of data, and displaying the subset of the plurality of data on a display device in a scrolling configuration.

In accordance with another embodiment, a method of determining carbon emissions from a facility can comprise manufacturing a first product with a first energy consuming device, determining energy useage of the first energy consuming device used for producing the first product, transmitting first data representing the energy usage of the first energy consuming device are producing the first product to a first server and further manufacturing the first product with a second energy consuming device. The method can also include determining energy usage of the second energy consuming device used for producing the first product transmitting second data representing the energy usage of the second energy consuming device used for producing the first product to the server, determining an amount of carbon emitted to produce the first product based on the determination of energy usage of the first energy consuming device and the determination of energy usage of the second energy consuming device, and transmitting third data representing the amount of carbon emitted from the server to a client device.

In accordance with another embodiment, a method of monitoring energy consumption or waste emissions from a facility, the method can comprise operating a plurality of devices, each of the plurality of devices either consuming energy or emitting waste, continuously detecting performance characteristics of each of the plurality of devices at a predetermined sampling rate, and transmitting data representing the performance characteristics of each of the plurality of devices to a server. The method can also include determining if the data transmitted to the server represents all of detected performance during the step of continuously detecting over a first predetermined limited amount of time, and storing an amount of the data corresponding the first predetermined limited amount of time in an area of a server reserved for data that has been verified as complete.

In accordance with another embodiment, a method of preparing data for analysis, can comprise sampling output from at least one sensor at a first frequency, storing data representing all of the output samples in the step of sampling, and storing a first subset of the data corresponding to first resolution lower than the data representing all of the output samples.

In accordance with another embodiment, a method of alerting a user of a system for collecting data representing performance characteristics of a facility wherein the system is configured to allow the user to request the data can comprise sampling the output of the plurality of sensors of a facility, storing data representing the output of the plurality of sensors, transmitting the data to a client device over a network in response to a request for the data from a user operating the client device, and transmitting an electronic message to the user without receiving a request from the user if the data satisfies a predetermined condition determined by the user.

### BRIEF DESCRIPTION OF THE DRAWINGS

The above-mentioned and other features of the inventions disclosed herein are described below with reference to the drawings of preferred embodiments. The illustrated embodiments are intended to illustrate, but not to limit the inventions. The drawings contain the following Figures:

FIG. 1 illustrates an overall block diagram of a system for optimizing energy use, in accordance with an embodiment.

FIG. 2 illustrates a block diagram of a base monitoring module usable with the system of FIG. 1.

FIG. 3 illustrates a block diagram of a Refrigeration Systems Module (RSM) usable with the system of FIG. 1.

FIG. 4 illustrates a block diagram of a Heating, Ventilation and Air Conditioning (HVAC) Module (ACM) usable with the system of FIG. 1.

FIG. 5 illustrates a block diagram of a Compressed Air Module (CAM) usable with the system of FIG. 1.

FIG. 6 illustrates a block diagram of a Boiler Systems Module (BSM) usable with the system of FIG. 1.

FIG. 7 illustrates a block diagram of a Thermal Systems Module (TSM) usable with the system of FIG. 1.

FIG. 8 illustrates a block diagram of a Motor and Process Load Module (PLM) usable with the system of FIG. 1.

FIG. 9 illustrates a block diagram of a Renewable Energy Systems Module (RES) usable with the system of FIG. 1.

FIG. 10 illustrates a block diagram of a network module useable with the system of FIG. 1.

FIG. 11 illustrates a block diagram of a data center and a client report interface of the system of FIG. 1.

FIG. 12 illustrates a flowchart of an exemplary embodiment of a data gathering process executable by the network module of FIG. 10.

FIG. 13 illustrates a flowchart of an exemplary embodiment of a data analysis process executable by the system of FIG. 1.

FIG. 14A illustrates a flowchart of an exemplary embodiment of an overall data analysis process executable by the system of FIG. 1.

FIG. 14B illustrates a flowchart of an exemplary embodiment of a validation process executable by the data center of FIG. 11.

FIG. 14C illustrates a flowchart of an exemplary embodiment of an aggregation process executable by the data center of FIG. 11.

FIG. 15 illustrates an exemplary screen display of a customer portal login screen controlled and generated by the system of FIG. 1.

FIG. 16A illustrates an exemplary screen display of a graphical user interface of a scrolling display tool controlled and generated by the system of FIG. 1.

FIG. 16B illustrates a flowchart of an exemplary embodiment of a method for configuring the scrolling display tool of FIG. 16A.

FIG. 16C illustrates a flowchart of an exemplary embodiment of a method for displaying real-time data via the scrolling display tool of FIG. 16A.

FIG. 17A illustrates a flowchart of an exemplary embodiment of a method for generating real-time alerts executable by the system of FIG. 1.

FIG. 17B illustrates an exemplary screen display of a graphical user interface for configuring alert definitions, in accordance with embodiments of the invention.

FIG. 18A illustrates an exemplary screen display of a graphical user interface for generating a report of emissions data across one or more facilities, in accordance with embodiments of the invention.

FIG. 18B illustrates an exemplary screen display of a chart generated from the selected parameters illustrated in FIG. 18A.

FIG. 18C illustrates an exemplary screen display of a summary table containing data corresponding to the chart illustrated in FIG. 18B.

FIG. 19 illustrates an exemplary screen display of a chart comparing emissions data from a previous year with emissions data for the current year, in accordance with embodiments of the invention.

FIG. 20 illustrates an exemplary screen display of a chart comparing actual energy consumption data with baseline levels, in accordance with embodiments of the invention.

FIGS. 21A-21G illustrate grids listing exemplary reports that can be generated to assess correlation between monitored data points of the modules of FIG. 1.

FIG. 22 illustrates an exemplary screen display of a graphical user interface for selection of monitored data points to compare in a correlation report, in accordance with embodiments of the invention.

FIG. 23 illustrates an exemplary screen display of a chart used to correlate plant electric demand with wet bulb temperature of an ice cream production facility over a defined interval, in accordance with embodiments of the invention.

FIG. 24 illustrates an exemplary screen display of a graphical user interface illustrating status of a boiler system of an energy consuming facility, in accordance with embodiments of the invention.

FIG. 25 illustrates an example of an optional screen display providing an interface for allowing a user to schedule reports to be run at predetermined intervals.

FIG. 26 illustrates an example of an optional screen display that can be used to allow a user to input a description and identifying information of events including characteristics that may not be detected by the instrumentation of the above noted systems.

FIG. 27 illustrates an example of an optional screen for displaying the events input with the screen illustrated in FIG. 26.

FIG. 28 illustrates another example of an optional screen for displaying the events input with the screen illustrated in FIG. 26.

FIG. 29 is another example of an optional screen for displaying the events input with the screen illustrated in FIG. 26.

FIG. 30 illustrates an optional screen for displaying a report and simultaneously displaying events input with the screen illustrated in FIG. 26.

FIG. 31 illustrates another example of an optional screen for displaying the events input with the screen illustrated in FIG. 26.

FIG. 32 illustrates an optional screen that can be provided for allowing a user to input restrictions on the number indoor time during which alerts are transmitted or received by a user.

### DETAILED DESCRIPTION OF THE PREFERRED EMBODIMENTS

The present embodiments generally relate to systems and methods for enabling energy efficiency optimization and reduction of environmental impact due to, for example, greenhouse gas emissions. The systems and methods disclosed herein can be developed or embodied in part or in whole in software that is running on one or more computing devices. In some embodiments, a method is provided that can optimize energy usage and environmental impact by controlling energy at one or more points of use and/or stream real time data to a user for informed decision making. This method can be particularly useful in industries which typically consume large amounts of to energy and/or waste emissions, such as for example but without limitation, food processing and manufacturing industries.

Some embodiments of the methods and systems disclosed herein can “green” customer revenue by quantifying and/or monetizing the greenhouse gas emissions reduced and/or “green” the bottom line by saving energy and its associated costs. Some embodiments can provide real-time operations monitoring information to expose hidden inefficiencies, opportunities for reductions, and/or savings. Some embodiments can also provide enhanced visibility and easy to use interfaces that managers can employ to reach their energy reduction goals. Such devices and/or methods can also provide critical sustainability information at the plant level, regional level, and/or at the national level.

In some embodiments, a system is provided that gathers, organizes and/or baselines all energy supply resources to one or more facilities into one convenient, usable and measurable source. The system can perform the same and/or similar functions for a subsystem of energy usage data. Such a system can gather real-time data from high quality analog or digital sensor or meter sources, including, for example, from several hundred to several thousand sources, depending on the size and needs of the facility, for real-time decision making. In some embodiments, a system can track and certify carbon emissions, energy use and automate demand response procedures to identify and take action on critical elements where efficiencies are the greatest. In some embodiments, such systems or methods can include industry standard processing systems such as for example but without limitation, Allen Bradley programmable logic controllers, SQL Databases, etc.

Some embodiments can provide mechanisms to green both top and bottom lines and can work well with demand response and other smart grid signals, as well as provide additional benefits beyond traditional systems. For example, some systems and/or methods can better assist decision-makers in deriving valuable insights into trends and cost-concerns, including when to replace equipment and realize costs savings. Such insights can improve both the top and bottom line because users may be able to reduce energy consumption and carbon emissions as well as measure their overall profitability more closely, for example, on a real-time, per product unit basis.

Some of the systems and/or methods disclosed herein can provide a real-time energy consumption and related CO₂ output at the point of use level. This can be particularly advantageous because it provides executives with information they need to inform their customers and shareholders of specific reductions their companies are making in energy use and carbon emissions on a product, facility or even company-wide basis, in both sustainable and financial terms.

Some of the systems disclosed herein can be configured to send data on a network, which can be secured, to an offsite or onsite facility for processing, report, and/or query preparation. In particular, the processing and/or reporting can continuously aggregate and pre-analyze the data and have it ready to quickly produce and display the data analysis upon request by the user, such as facility and/or executive management. The pre-analysis of data can include analyzing the data for a plurality of time resolutions, such as last week, last month, last year, past 7 days, past 30 days, past 6 months, current day, current week, current month and the like. In some embodiments, the pre-analysis of data can include the calculation of new data based corresponding to standard reports commonly requested by management personnel. The pre-analysis of data at the back end advantageously reduces the processing time required at the front end to display the data reports to the end user.

In some embodiments, the system can be integrated with one or more modules, including energy efficiency and control modules, which can send alarms and/or process control information to the energy consumption systems being monitored. Advantageously, the system can integrate plant production information with energy and/or emission data, which can result in improved production and capital decisions. In addition, the system can generate and report the carbon footprint of each facility for regulatory reporting and compliance purposes. In some embodiments, the system can be scalable to include multiple facilities and/or enterprises.

Generally, the systems and methods disclosed can enable real-time decision making and/or provide an eagle-eye view of the macro enterprise level to facilitate management at the micro level of energy use and/or emissions. In some embodiments, profiles can be created that measure energy usage and/or greenhouse gas emissions. This can be particularly useful for providing users, such as corporations, with key performance indicators, such as a carbon footprint, at a product level on a periodic basis.

For purposes of describing the embodiments herein, certain aspects, advantages and novel features of those various embodiments have been described in detail. Of course, it is to be understood that not necessarily all such aspects, advantages or features will be embodied in any particular embodiment of one or more of the inventions.

Each of the processes, components, and algorithms described above can be embodied in, and fully automated by, code modules executed by one or more computers or computer processors. The code modules can be stored on any type of computer-readable medium or computer storage device. The processes and algorithms can also be implemented partially or wholly in application-specific circuitry. The results of the disclosed processes and process steps can be stored, persistently or otherwise, in any type of computer storage. In one embodiment, the code modules can advantageously be configured to execute on one or more processors. In addition, the code modules can comprise, but are not limited to, any of the following: software or hardware components such as software object-oriented software components, class components and task components, processes methods, functions, attributes, procedures, subroutines, segments of program code, drivers, firmware, microcode, circuitry, data, databases, data structures, tables, arrays, variables, or the like.

In general, the word “module,” as used herein, refers to logic embodied in hardware or firmware, or to a collection of software instructions, possibly having entry and exit points, written in a programming language, such as, for example, Java, Lua, Objective-C, C or C++. A software module may be compiled and linked into an executable program, installed in a dynamic link library, or may be written in an interpreted programming language such as, for example, BASIC, Perl, or Python. It will be appreciated that software modules may be callable from other modules or from themselves, and/or may be invoked in response to detected events or interrupts. Software instructions may be embedded in firmware, such as an EPROM. It will be further appreciated that hardware modules may be comprised of connected logic units, such as gates and flip-flops, and/or may be comprised of programmable units, such as programmable gate arrays or processors. The modules described herein are preferably implemented as software modules, but may be represented in hardware or firmware. Generally, the modules described herein refer to logical modules that may be combined with other modules or divided into sub-modules despite their physical organization or storage.

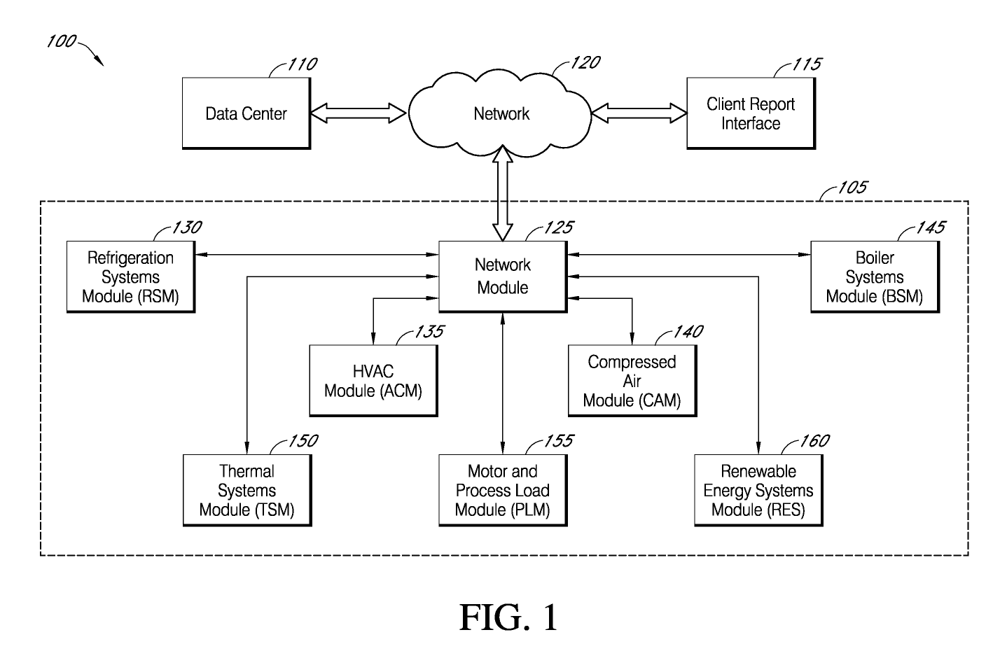

FIG. 1 is a block diagram of a system 100 that can be used to monitor and/or optimize energy use and environmental impact, in accordance with some embodiments. In the illustrated embodiments, an energy consuming facility 105, a data center 110 and a client report interface 115 are in communication with a network 120. The energy consuming facility 105 can be used to implement certain systems and methods described herein. Energy consuming facility 105 can comprise a manufacturing or production facility, such as a dairy facility, an ice cream production facility, a farming facility, a pet food production facility, and/or any other type of facility having at least one energy consuming device.

Communication over the network 120 can take place using sockets, ports, and/or other mechanisms recognized in the art. The network 120 can comprise a public network such as the Internet, a virtual private network (VPN), a token ring or TCP/IP based network, a wide area network (WAN), a local area network (LAN), an intranet network, a point-to-point link, a wireless network, a cellular network, a telephone network, a wireless data transmission system, a two-way cable system, a satellite network, a broadband network, a baseband network, combinations of the same, or the like. The network 120 communicates with various computing devices and/or other electronic devices via wired or wireless communication links.

In general, the data center 110 receives data from the energy consuming facility 105 regarding resource usage, such as electricity, natural gas and water, waste emissions, and/or other processes in order to generate reports regarding energy consumption and emissions to be accessed via client report interface 115. In some embodiments, the data center 110 can comprise a database server system of multiple physical computers and associated content that are accessible via the network 120. In other embodiments, the data center 110 can be a stand-alone computing system, such as a personal computer that is IBM, Macintosh, or Linux/Unix compatible. Those skilled in the art will appreciate, that the data center 110 can comprise other computer system configurations, including hand-held devices, multi-processor systems, microprocessor-based or programmable consumer electronics, minicomputers, mainframe computers, and the like.

Data center 110 can be implemented using physical computer servers that are geographically remote from one another and from the energy consuming facility 105 and/or can include content that spans multiple internet domains. Data center 110 and/or client report interface 115 can be accessible by one or more energy consuming facilities via the network 120. In some embodiments, the data center 110 is a centralized remote database for multiple energy consuming facilities and/or multiple enterprises. However, the functionality provided for in the various components described herein can be combined and/or further separated in different embodiments. For example, in some embodiments, the data center 110 and/or the client report interface 115 can be provided at the energy consuming facility 105 itself.

The client report interface 115 is the user access device through which the user interacts with the system 100. As indicated by the arrows pointing to and away from the client report interface 115, the client report interface 115 is the means by which requests are submitted to the system 100, and the means by which reports and other responses are received by users. Users can interact with the system 100 through a wide variety of user access devices. The client report interface 115 can comprise any type of client device capable of communicating with the data center 110 via the network 120. For example, the client report interface 115 can comprise a network computer, a server, a PDA, a workstation, a smartphone, a laptop, a virtual device, or the like. In some embodiments, the client report interface 115 comprises a display device configured to display reports, such as graphical charts, of monitored data from various plants or facilities being monitored by the energy optimization system 100. More particularly, a display device provides for the presentation of scientific data, GUIs, application software data, and multimedia presentations, for example. The client report interface 115 can comprise one or more input devices, such as a keyboard and/or a mouse and a network communication device. The client report interface 115 can also include one or more multimedia devices, such as speakers, video cards, graphics accelerators, and microphones, for example.

Energy consuming facility 105 can include an network module 125 in communication with data center 110 and/or client report interface 115 via the network 120. The communication of all entities through a common network 120 is illustrative only, and the invention includes embodiments where some entities communicate through one network, other entities through a different network, and various permutations thereof.

A network module 125 can be used to collect, store, and/or organize data from a variety of sensors, meters and/or other input sources. For example, the network module 125 can comprise a base module that monitors basic energy consumption sources of the facility, such as total electric energy consumption, total gas consumption, and total water consumption. The network module 125 can also collect data from other add-on modules configured to monitor more specific data points of various systems of the energy consuming facility, such as a refrigerator system or a boiler system, for more refined analysis and improved cost savings. In some embodiments, the network module 125 forwards the accumulated data from the input sources and other modules to the data center 110 on a periodic basis via the network 120 for further processing and analysis.

As depicted in FIG. 1, the network module 125 can communicate with various other modules which can include, for example but without limitation, a refrigeration systems module 130, HVAC module 135, compressed air module 140, boiler systems module 145, thermal systems module 150, motor and process load module 155, renewable energy systems module 160, and/or other modules, sensors, or devices.

The network module 125 can monitor, aggregate, archives and/or report information from the modules noted above. In some embodiments, these modules monitor and/or control energy use and emissions information, which can be used for feedback control and/or reporting purposes. Each of the modules noted above can include a controller, such as an Allen Bradley programmable logic controller, that sends data to the network module 125 over a network at the energy consuming facility 105. In some embodiments, the various modules can also include a computing system for processing data, a memory for storing data, and a network communication device for communicating data. The list of modules provided is not intended to be exhaustive, and it should be appreciated that network module 125 can communicate with other modules that are not specifically described herein.

In some embodiments, refrigeration module 130 can provide a detailed energy profile for refrigeration systems and/or control of refrigeration systems. HVAC module 135 can, for example, provide data sufficient for a detailed energy profile for heating, ventilating, and/or air conditioning systems and/or control of such systems. Compressed air module 140 can, in some embodiments, provide sufficient data for a detailed energy profile for compressed air systems and/or control of such systems. Boiler systems module 145 can, in some embodiments, provide sufficient data for a detailed energy profile for boiler systems and/or control of such systems.

Similarly, thermal systems module 150 can, in some embodiments, provide sufficient data for a detailed energy profile for thermal systems and/or control of such systems. Motor and process load module 155 can, in some embodiments, provide sufficient data for a detailed energy profile for process loads and motors and/or control of such systems. Renewable energy systems module 160 can, in some embodiments, provide sufficient data for a detailed energy profile and/or operating characteristics of renewable energy systems, and/or control of such systems. The various modules can include sensors, meters, hardware components, software, and/or computing systems.

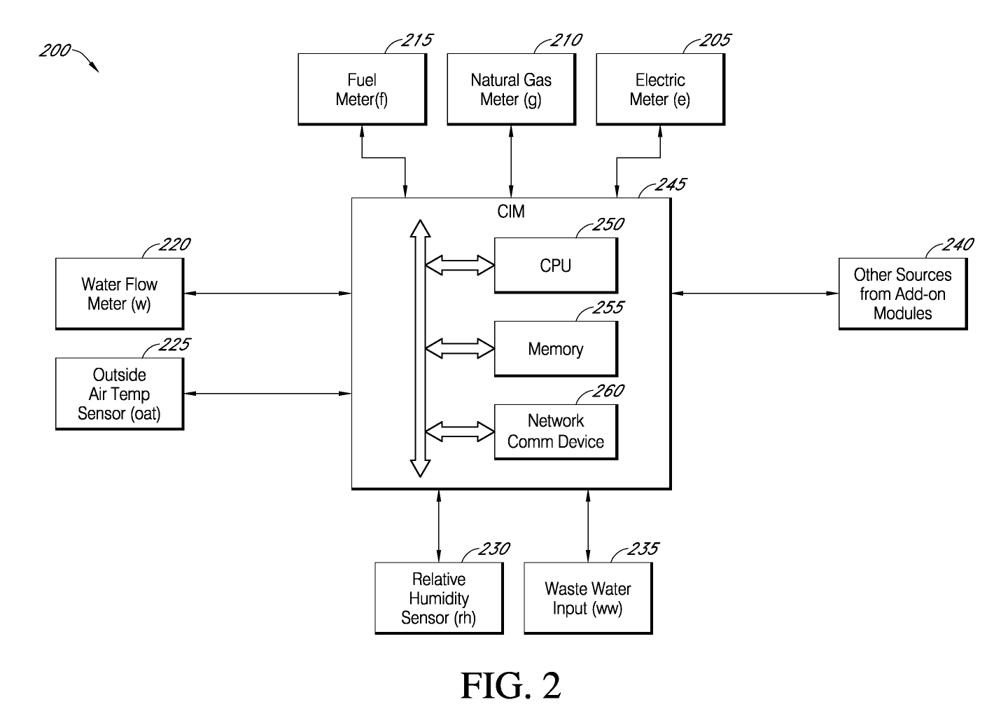

In some embodiments, network module 125 comprises a base monitoring module, which can also be referred to as a CERS initiation module (CIM). FIG. 2 illustrates a block diagram of a CIM 200, in accordance with an embodiment. In some embodiments, the CIM 200 can comprise basic input sources to monitor and/or optimize overall energy consumption and emission reduction of a facility.

For example, the CIM 200 can include an electricity consumption meter 205, a natural gas consumption meter 210, and an alternate fuel consumption meter 215. Additionally, the CIM 200 can include a water flow meter 220, an outside air temperature sensor 225, and/or a relative humidity sensor 230. In some embodiments, a waste water consumption value 235 can be provided as an input to the CIM 200 by a user. Additional types of measurements can also be taken by other sources 240 in communication with network module 125 via the various add-on modules illustrated in FIG. 1. In some embodiments, the network module 125 can transmit control signals, or commands, to the various modules, which can then be relayed to the appropriate components of the monitored systems at the energy consuming facility 105.

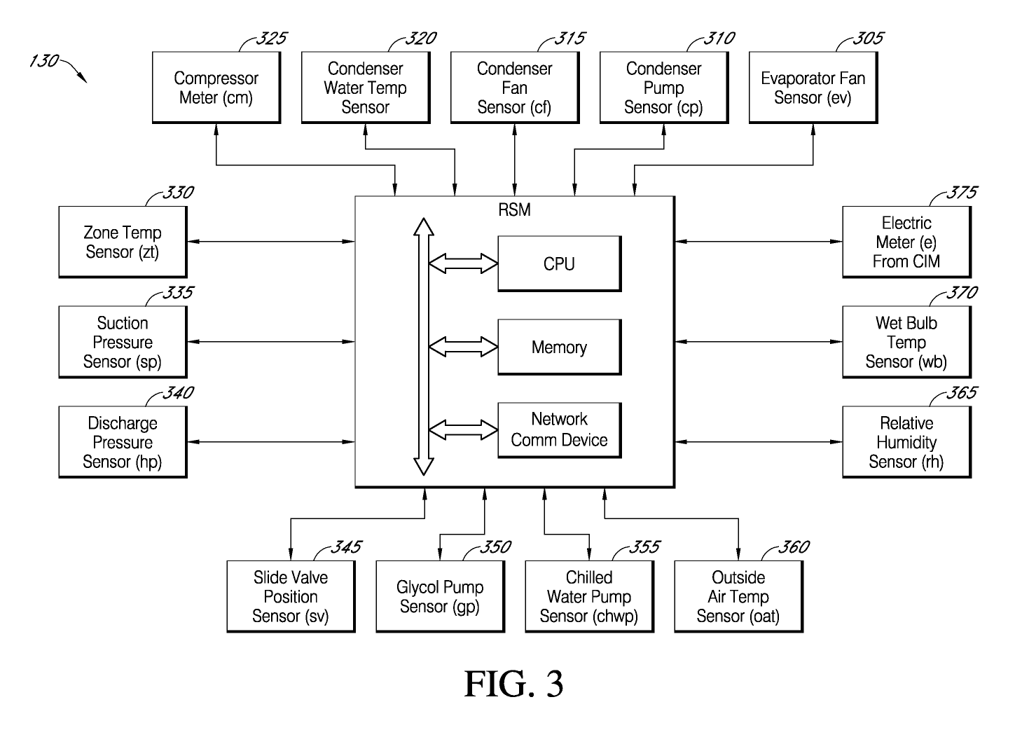

As further illustrated in FIG. 2, the CIM 200 of network module 125 can comprise an electronic control unit 245. Electronic control unit 245 can include a central processing unit (“CPU”) 250, which may include a conventional microprocessor. The electronic control unit 245 can further include a memory 255, such as random access memory (“RAM”) for temporary storage of information and/or a read only memory (“ROM”) for permanent storage of information. Additionally, electronic control unit 245 can include a network communications device 260. In some embodiments, the modules of the electronic control unit 245 are connected using a standards based bus system, such as Modbus. In other embodiments, the standards based bus system could be Peripheral Component Interconnect (PCI), Microchannel, SCSI, Industrial Standard Architecture (USA) and Extended ISA (EISA) architectures. Similar to the CIM 200, each of the add-on modules, as illustrated in FIGS. 3-9, can also include an electronic control unit having a central processing unit, a memory and a network communications device. However, in other embodiments, all the various sensors and actuators over more of the various modules noted above can be directly connected to a control device, such as a programmable logic controller, included within the network module 125.

To facilitate the exchange of data with various modules, the network module 125 can use a network (not shown) at energy consuming facility 105 configured to allow the network module 125 to control and/or communicate with the various modules. The network can run over ethernet, such as AB ethernet IP. The network can be distributed using, for example, CAT5 cable, fiber, and/or wireless radios depending on the distances and/or difficulty of wiring at the energy consuming facility 105. Additional communications with PLC systems, such as older Allen Bradley PLCs can be managed by a controller, such as a CompactLogix controller, as well as DH+ and/or DF1 protocols. Once data is collected from the various input sources by the network module 125, the data can be preprocessed by a processor (e.g., CPU 250) and/or stored in a local memory storage device (e.g., memory 255).

FIG. 3 illustrates a block diagram of the refrigeration systems module (RSM) 130. The refrigeration systems module 130 can be configured to provide data sufficient for a detailed energy profile for a refrigeration system and/or control of the refrigeration system. The refrigeration systems module 130 can, in some embodiments, track efficiency of a refrigeration system as a function of ambient air temperature and/or other variables. On the other hand, the refrigeration systems module 130 can include only a more limited number of sensors under actuators.

As illustrated in FIG. 3, the refrigeration systems module 130 can include numerous sensors or other input sources. For example but without limitation, input sources can be included that, in some embodiments, monitor electricity consumption, temperature, and/or pressure levels of various components of a refrigeration system, such as a compressor, condenser and/or evaporator. The illustrated embodiments of refrigeration systems module 130 include an evaporator fan sensor 305, a condenser pump sensor 310, a condenser fan sensor 315, a condenser water temperature sensor 320, a compressor meter 325, a zone/process temperature sensor 330, a suction pressure sensor 335, a discharge pressure sensor 340, and a slide valve position sensor 345. Additionally, the refrigeration systems module 130 can include sensors that detect electricity used by a glycol pump and/or chilled water pump, such as glycol pump sensor 350 and chilled water pump sensor 355.

Refrigeration systems module 130 can further include an outside air temperature sensor 360, a relative humidity sensor 365, and a wet bulb temperature sensor 370. In some embodiments, other measurements can be taken by other input sources included in the refrigeration systems module 130. For example, the sensors of the refrigeration systems module 130 can also detect electricity 375 from the CIM 200 of network module 125. The sensors and actuators specifically listed above are merely examples of some of the types of sensors and actuators that can be included in a refrigeration type module. It is to be understood that any such refrigeration module, or any of the other modules described below, used in conjunction with any of the embodiments and/or inventions disclosed herein, can be instrumented and/or configured with fewer or additional sensors under actuators or other devices, in accordance with the ultimate goals of the user.

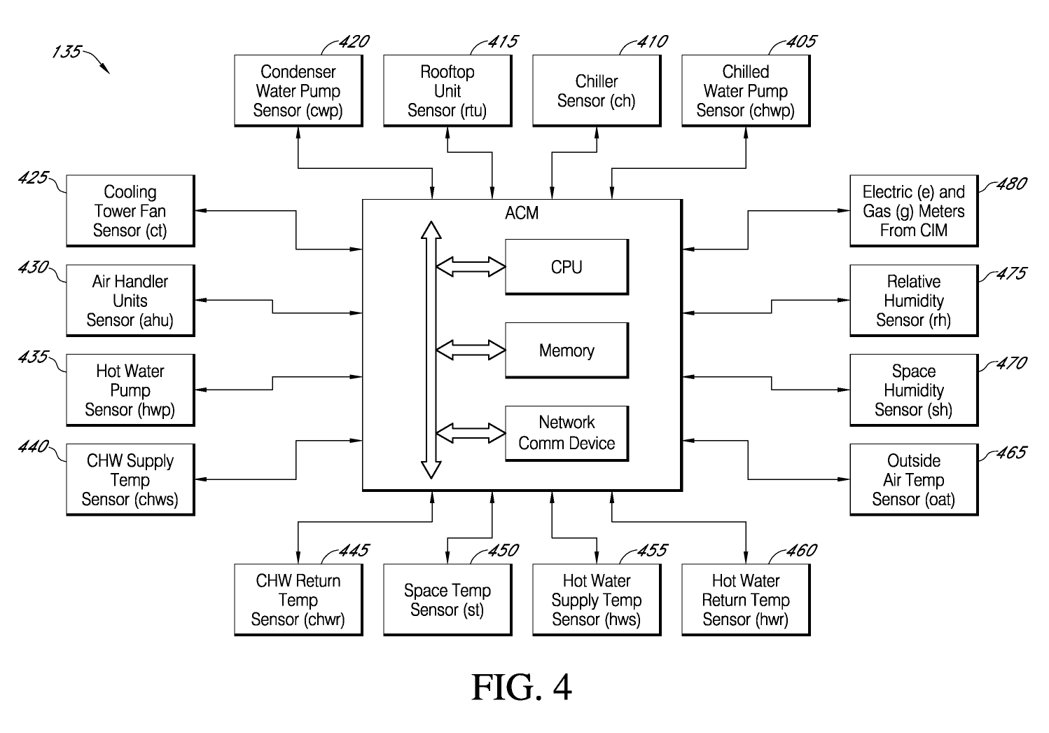

FIG. 4 illustrates a block diagram of the HVAC module (ACM) 135. In the illustrated embodiments, the HVAC module sensors include a chilled water pump sensor 405, a chiller sensor 410, a rooftop unit sensor 415, a condenser water pump sensor 420, a cooling tower fan sensor 425, an air handler unit sensor 430, and/or a hot water pump sensor 435. In some embodiments, these sensors detect electricity consumption. Additionally, HVAC module 135 can include temperature sensors such as chilled water supply temperature sensor 440, chilled water return temperature sensor 445, space temperature sensor 450, hot water supply temperature sensor 455, hot water return temperature sensor 460, and/or outside air temperature sensor 465. In some embodiments, the HVAC module 135 includes a space humidity sensor 470 and a relative humidity sensor 475. The sensors of the HVAC module 125 can also detect electricity and gas measurements 480 from the CIM 200 of network module 125. In some embodiments, other measurements can be taken by sensors of the HVAC module 135, including flow metering on chilled water, hot water, and/or cold water.

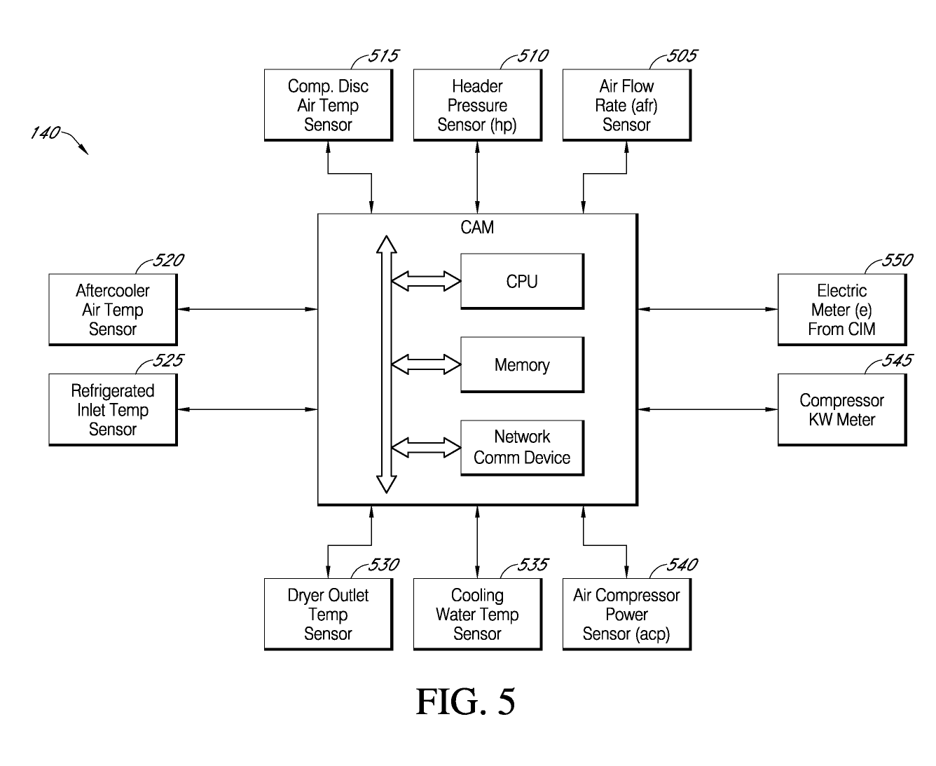

FIG. 5 illustrates a block diagram of compressed air module (CAM) 140. Compressed air module 140 can include a variety of input sources to monitor flow, pressure, temperature, power and electricity. In the illustrated embodiments, the compressed air module 140 includes an air flow rate sensor 505, a header pressure sensor 510, a compressor disc air temperature sensor 515, an aftercooler air temperature sensor 520, a refrigerated inlet temperature sensor 525, a dryer outlet temperature sensor 530, a cooling water temperature sensor 535, an air compressor power sensor 540, and a compressor kW meter 545. Additional measurements, such as electricity 550 from the CIM 200 of network module 125, can be taken by other input sources included in the compressed air module 140.

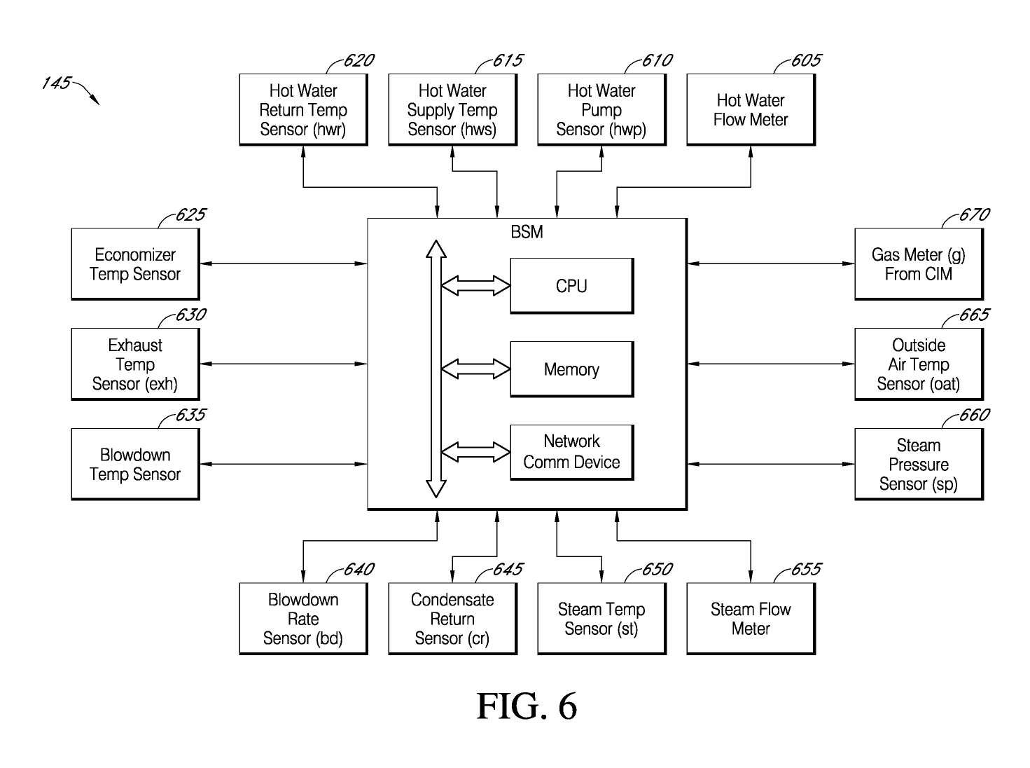

FIG. 6 illustrates a block diagram of boiler systems module (BSM) 145. Boiler systems module 145 can include a variety of input sources to monitor various components of a boiler system. The illustrated embodiments include a hot water flow meter 605, a hot water pump sensor 610, a hot water supply temperature sensor 615, a hot water return temperature sensor 620, an economizer temperature sensor 625, an exhaust temperature sensor 630, a blowdown temperature sensor 635, a blowdown rate sensor 640, a condensate return sensor 645, a steam temperature sensor 650, a steam flow meter 655, a steam pressure sensor 660, and an outside air temperature sensor 665. Additional measurements, such as total natural gas usage from the CIM 200, can be taken by other sensors 670 included in the boiler systems module 145.

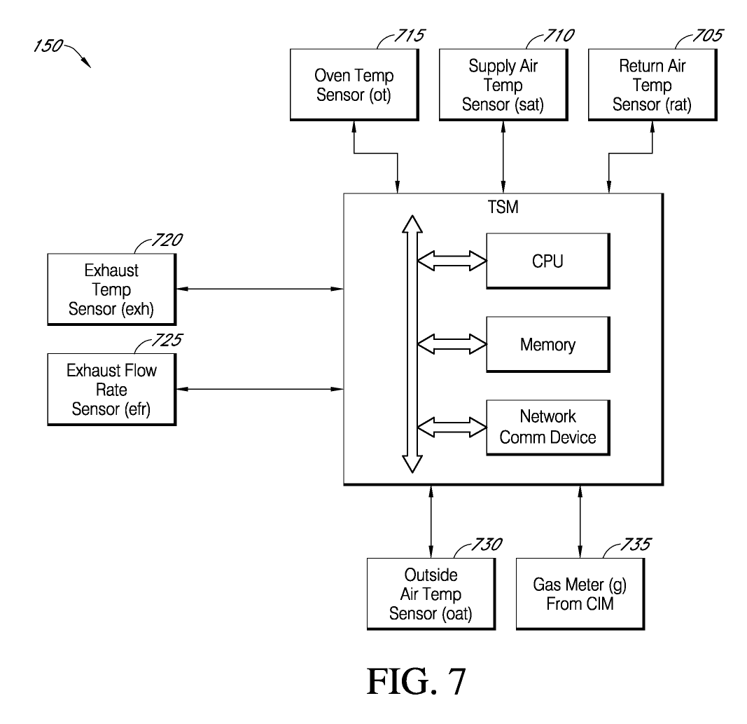

FIG. 7 illustrates a block diagram of thermal systems module (TSM) 150. Thermal systems module 150 can include various rate and temperature sensors in some embodiments. The illustrated embodiments include a return air temperature sensor 705, a supply air temperature sensor 710, an oven temperature sensor 715, an exhaust temperature sensor 720, an exhaust flow rate sensor 725, an outside air temperature sensor 730, and a gas meter 735 from the CIM 200. Additional measurements can be taken by other sensors included in the thermal systems module 150.

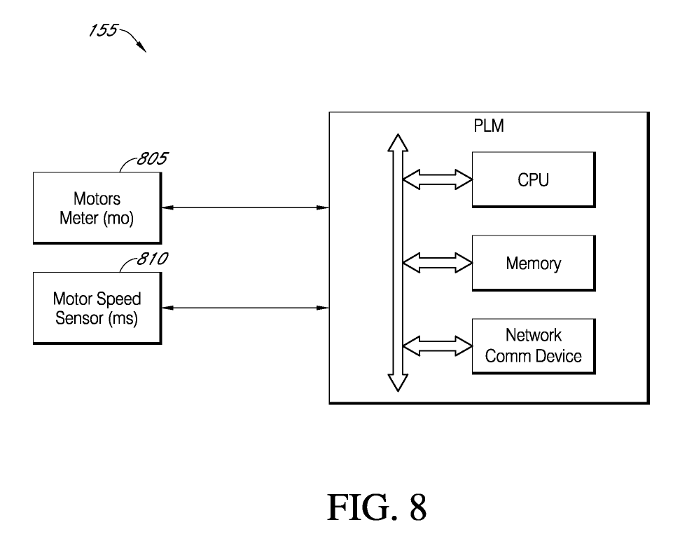

FIG. 8 illustrates a block diagram of a motor and process load module (PLM) 155. As shown, motor and process load module 155 can include various motor electrical meters 805 and motor speed sensors 810. Additional measurements can be taken by other sensors included in the motor and process load module 155.

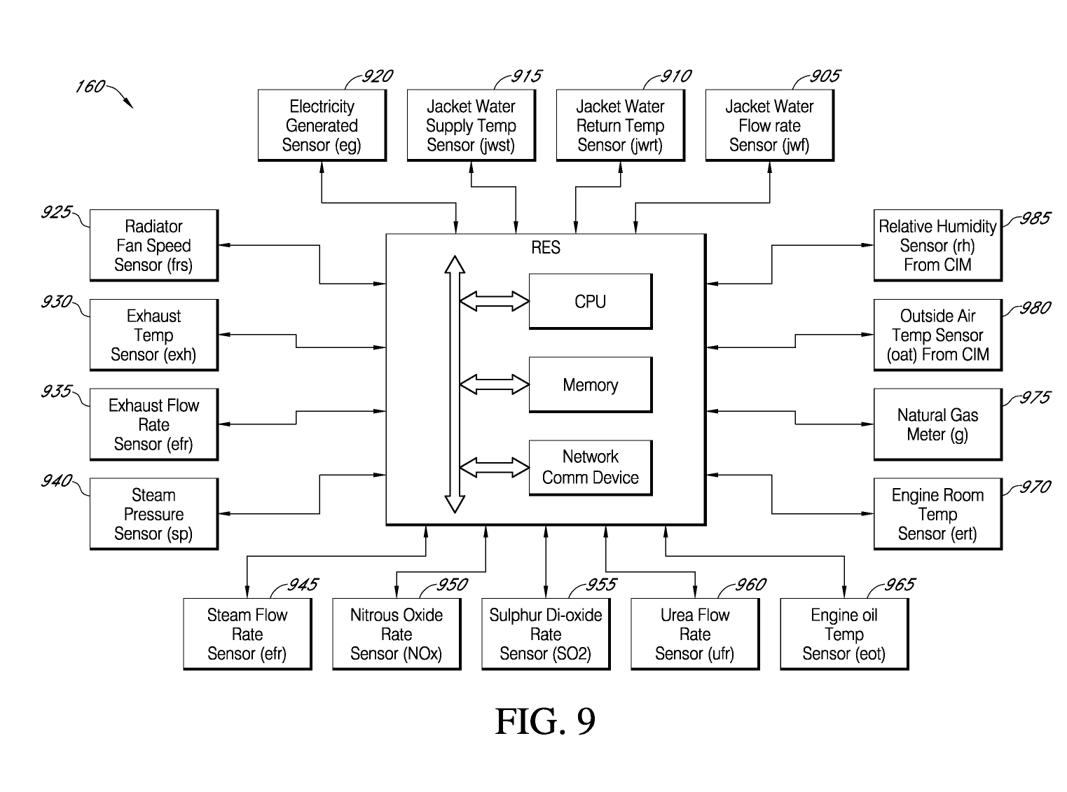

FIG. 9 illustrates a block diagram of a renewable energy systems module (RES) 160. Although FIG. 1 illustrates only a single renewable energy systems module 160, the energy optimization system 100 can include one or a plurality of such modules, described in greater detail below. Additionally, although only a single type of renewable energy systems module 160 is described below, the energy optimization system 100 can include other types of renewable energy systems modules. For example, the energy optimization system 100 can include modules configured for monitoring and/or controlling systems for recovering waste gases (e.g., methane gas), waste substances, waste heat, etc., any of which may also be configured to prepare, transmit, and/or supply such recovered waste for consumption in another system. For example, recovered methane gas can be used as a fuel in another energy consuming device within the energy optimization system 100. Thus, the renewable energy systems modules 160 described below include some of the typical sensors, meters, and/or other instrumentation or actuators associated with some typical such modules. However, in any particular application, as with the other modules disclosed herein, other instruments, meters, and actuators can also be used. As such, the energy optimization system 100 can be described as including one or plurality of any combination of energy consuming devices, energy generation devices, waste emitting devices, and waste recovery devices.

Additionally, it is to be understood that although none of the devices described herein either generate or consume energy as such would violate the law of the conservation of energy, those of ordinary skill in the art will understand that an electric motor and fuel fired boilers would be considered “energy consuming devices”, but on the other hand, electric generators driven by steam pressure generated from waste heat would be considered “energy generation devices”, as those terms are used herein.

The renewable energy systems module 160 can include a variety of temperature, rate, speed, pressure, and other input sources. The illustrated embodiments include a jacket water flow rate meter 905, a jacket water return temperature sensor 910, a jacket water supply temperature sensor 915, an electricity generated meter 920, a radiator fan speed sensor 925, an exhaust temperature sensor 930, an exhaust flow rate meter 935, a steam pressure sensor 940, a steam flow rate meter 945, a nitrous oxide rate meter 950, a sulphur dioxide rate meter 955, a urea flow rate meter 960, an engine oil temperature sensor 965, an engine room temperature sensor 970, and a natural gas meter 975. As noted above, the renewable energy systems module 160 can also be configured to recover waste gases, including those having the potential for conversion into electrical energy, for example, but without limitation, methane gas which can be combusted to generate steam for power generation or two drive an internal combustion engine directly driving electrical generator for a logical energy generation. Thus, a meter such as the natural gas meter 975 can be configured to detect a flow of such waste methane gas. Additionally, the renewable energy systems module 160 can also include outside air temperature 980 and a relative humidity sensor measurements 985 from the CIM 200.

It should be appreciated by one of ordinary skill in the art that additional input sources can be included in any of the illustrated modules. Although the input sources have been described as meters or sensors, the input sources should not be limited to one or the other. Generally, meters are used to measure cumulative values and sensors are used to monitor real-time values. However, in different embodiments, an input source labeled as a meter can be a sensor and an input source labeled as a sensor can be a meter, depending on the measurement desired. In some embodiments, the various temperature sensors can comprise resistance temperature detectors (RTDs).

Additionally, each of the modules illustrated in FIGS. 3-9 can issue commands to control the various components of the system being monitored by the module in order to optimize energy consumption and reduce emissions. For example, the boiler systems module 145 can issue commands to shut down the boiler during periods of plant inactivity. As another example, the refrigeration systems module 130 can issue commands to periodically reset the discharge pressure of a compressor. In some embodiments, commands can be generated to cause the monitored systems to engage in peak load shaving.

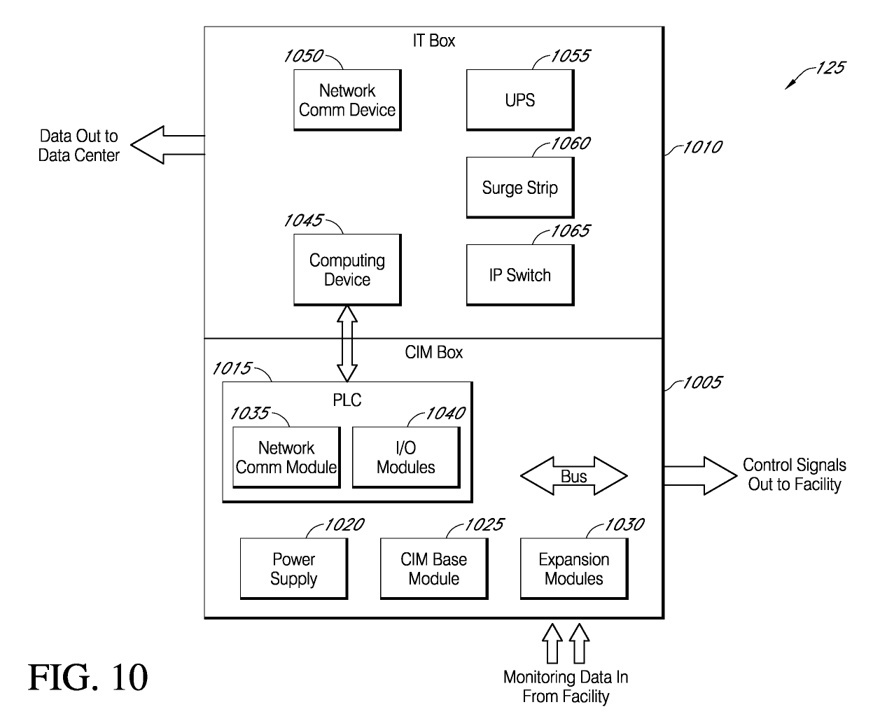

FIG. 10 is a block diagram of the network module 125 of FIG. 1. As shown, the network module 125 can comprise a “CIM” box 1005 and an “IT” box 1010. In some embodiments, the CIM box 1005 and the IT box 1010 can be located in the same physical housing. In other embodiments, the CIM box 1005 and the IT box 1010 can be located in separate housings at different locations at the energy consuming facility 105. In other embodiments, the CIM box 1005 can be separated into multiple sub-components spread throughout the facility 105.

The CIM box 1005 and IT box 1010 can be in communication with each other via a local area network. As discussed above, the local area network can comprise an ethernet network, such as AB ethernet IP, and or other types of networks operating in accordance with other network communication protocols. The network can be distributed using, for example, CAT5 cable, fiber, and/or wireless radios depending on the distances and/or difficulty of wiring at the energy consuming facility 105.

The CIM box 1005 can include a programmable logic controller (PLC) 1015, a power supply 1020, a CIM base module 1025 and, optionally, expansion or add-on modules 1030. The PLC 1015 can include a network communications module 1035 and various input/output modules 1040. The input/output modules 1040 can include analog and/or digital modules. In some embodiments, the input/output modules 1040 may be built into the PLC 1015. In other embodiments, the input/output modules 1040 can be located external to the PLC 1015 and can communicate with the PLC 1015 via a network. For example, but without limitation, the PLC 1015 can comprise an Allen Bradley programmable logic controller communicating directly with all the above noted sensors, actuators, and/or other devices described above with reference to the individual modules. In such embodiments, the PLC 1015 can be configured to directly, periodically sample the outputs of all of the sensors, meters, and/or other devices and to transmit data representing such sampling to the IT box 1010, described in greater detail below. Additionally, the PLC 1015 can be configured to provide output signals to any actuators or other devices.

Generally, the CIM box 1005 continuously polls all the input sources associated with the various systems being monitored by the modules of the CIM box 1005 and sends control signals out to the facility 105. In some embodiments, the CIM box 1005 can include an Allen Bradley CompactLogix system. In some embodiments, the PLC 1015 can comprise an AB 1769-L32E programmable logic controller with ethernet connectivity.

The power supply 1020 can comprise an AB 1769-PA4 heavy duty power supply. The input/output modules 1040 of the PLC 1015 can comprise an AB 1769-IF4 analog input module (including, for example, 4 current (ma) channels), an AB 1769-OF2 analog output module with current (ma) channels, an AB 1769-IQ16 digital input module (including, for example, 16 24VDC digital inputs) and an AB 1769-OB8 digital output module (including, for example, 8 digital outputs). In some embodiments the PLC 1015 can be configured to convert analog signals received into digital signals readable by a computing device.

In some embodiments, the communications module 1035 comprises a Prosoft MVI69 communications module that can be configured for Modbus RTU. In some embodiments, the network module 125 can also include the following: AB relay output terminals with “C” form dry contacts (rated at, for example, 10 amps, 125 VAC), Altech 24 VDC, 24 watt power supply (that can provide, for example, power for relays and loop power), and/or DIN 2A circuit breakers that can provide protection for power supplies and/or outputs. The operating specifications of the network module 125 can be, in some embodiments, the following: 120 VAC input power, circuit breaker protected, 150 watts maximum load, ambient temperature rating from −10 F to +95 F non-condensing, isolated output circuit relays rated at 10 A, 250VAC maximum, and/or environmental protection from dust and light water spray.

In some embodiments, the IT box 1010 can be configured to: a) gather data across the network from the various modules, using, for example, an ethernet connection; b) organize and/or store the data in a local database, using, for example, a structure custom to each site and/or dependent on the control data being collected; and/or c) forward the data on a periodic basis to data center 110 for storage in a database. In some embodiments, the raw data collected can be accessed at the energy consuming facility 105.

The IT box 1010 can comprise a computing device 1045, a network communication device 1050, a universal power supply (UPS) 1055, an IP surge strip 1060, and an IP switch 1065. In some embodiments, the computing device 1045 comprises a USDT form factor Windows XP Pro PC or HP industrial PC. The computing device 1045 can include a central processing unit, which can include one or more conventional microprocessors, a memory, which can include random access memory or read only memory, and a mass storage device, such as one or more hard drives, diskettes, and/or optical media storage devices. The computing device 1045 can include any of the following software: Rockwell RS Logix 5000 integrated programming software, Windows XP Pro® operating system, MS Express SQL database, OPC compliant driver for the Allen Bradley PAC data, Inductive Automation “Factory SQL” ODBC database interface, and/or Inductive Automation “Factory PMI” SQL interface HMI visualization software for locally hosted web pages.

The network communication device 1050 can comprise a router, such as a Cisco 2811 router. The network communication device 1050 can be used to transfer data over the network 120 to data center 110. In some embodiments, the network connection can be over the internet and/or be an encrypted VPN connection, such as IPSec or SSL. Network module 125 can advantageously be accessed remotely, by, for example, data center 110 using the network 120. In some embodiments, one or more exchange point modules 125 include an internet connection with a static IP address. The connection can be over any medium. The connection and ISP account can be managed by the data center 110 and/or the energy consuming facility 105. The UPS 1055 can comprise, for example, a 750 kVA UPS. In some embodiments, the IP switch 1065 comprises a KVM over IP switch.

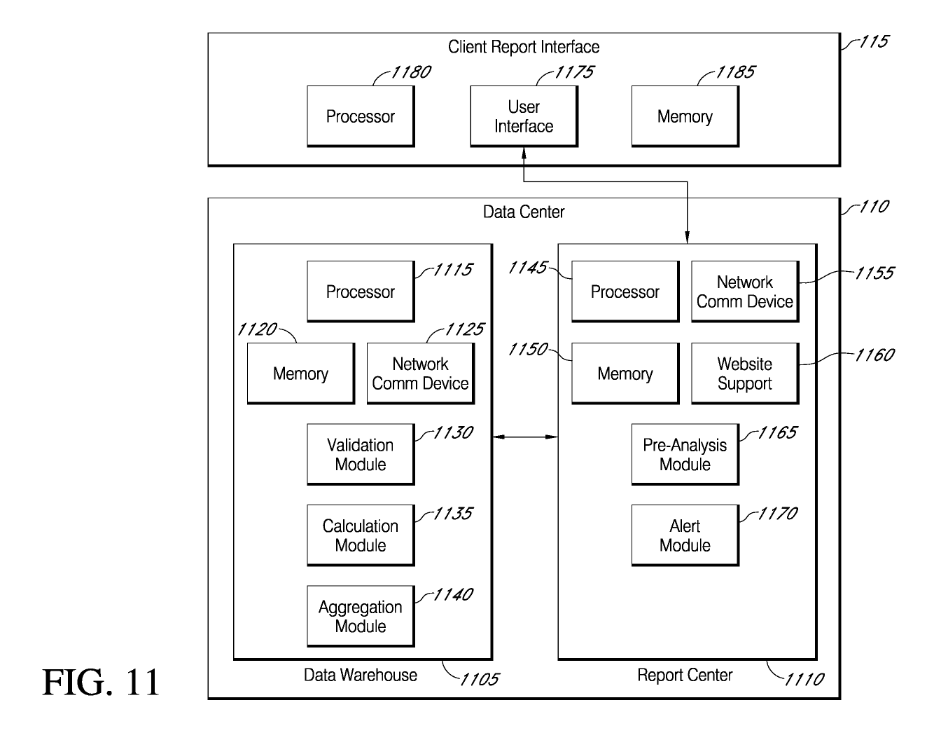

FIG. 11 illustrates embodiments of the data center 110 and the client report interface 115. As shown, the data center 110 can include a data warehouse server 1105 and a report center server 1110. It should be appreciated, however, that the data warehouse server 1105 and/or the report center server 1110 can comprise multiple database servers. For example, the data center 110 can include a separate data warehouse server and/or report center server for each enterprise and/or facility. In other embodiments, the data warehouse server 1105 and the report center server 1110 can comprise a single server. It should be appreciated that other distributed computing systems can also be employed.

The data warehouse server 1105 can include a processor 1115, a memory 1120, a network communication device 1125, a validation module 1130, a calculation module 1135, and an aggregation module 1140. In some embodiments, the processor 1115 comprises a general or a special purpose microprocessor. The processor 1115 can comprise an application-specific integrated circuit (ASIC) or one or more modules configured to execute on one or more processors. The processor 1115 can communicate with the memory 1120 to retrieve and/or store data and/or program instructions for software and/or hardware. The processor 1115 can be configured to execute the validation module 1130, the calculation module 1135 and the aggregation module 1140. The data warehouse server 1105 can also include relational database software to be executed by the processor 1115. In some embodiments, one or more of the data sources can be implemented using a relational database, such as Sybase, Oracle, CodeBase, MySQL and Microsoft® SQL Server, as well as other types of databases such as, for example, a flat file database, an entity-relationship database, an object-oriented database, and/or a record-based database.

The memory 1120 can include, for example, local temporary storage, such as random access memory or read-only memory, and/or a mass storage device, such as one or more hard drives, disks, and/or optical media storage devices, for permanent storage of information. The network communication device 1125 can comprise a router for receiving data from the network module 125 via the network 120 and for transmitting data to the report center server 1110.

In some embodiments, the validation module 1130, can be configured to determine whether the data received from the network module 125 is valid or not. If the data is valid, it is stored for further processing. If the data is invalid, an error is logged in an audit table for further attention. In some embodiments, the calculation module 1135 can be configured to, for example, upon execution by the processor 1115, calculate new data for reporting by applying predetermined formulas to the validated data. The aggregation module 1140 can be configured to, for example, upon execution by the processor 1115, aggregate the data received from the network module 125 over a defined interval, such as a quarter hour, an hour, a day, a week, a month, and the like.

The report center server 1110 can include a processor 1145, a memory 1150, a network communication device 1155, a website support module 1160, a pre-analysis module 1165, and an alert module 1170. In some embodiments, the processor 1145 comprises a general or a special purpose microprocessor. The processor 1145 can comprise an application-specific integrated circuit (ASIC) or one or more modules configured to execute on one or more processors. The processor 1145 can communicate with the memory 1150 to retrieve and/or store data and/or program instructions for software and/or hardware. The memory 1150 can include random access memory (“RAM”) for temporary storage of information and/or read only memory (“ROM”) for permanent storage of information.

In some embodiments, the network communication device 1155 comprises a router configured to receive data from the data warehouse server 1105 and transmit data to the client reporting interface 120. The website support module 1160 can comprise one or more modules that can be configured to run and support a website to display reports of the data collected by the network module 125 in a web page format. The presentation of data to the user can include charts, tables, alerts, and continuous scrolling displays that a user can view or interact with. The services provided by the website support module 1160 include security, HTML interfaces, and/or the like. In some embodiments, the report center server 1110 includes miscellaneous networking gear, such as switches and/or firewalls; software to troubleshoot, maintain, and/or monitor the website; and/or services, such as Active Directory, time, email, and/or the like.

In some embodiments, the pre-analysis module 1165 can be configured to, for example, upon execution by the processor 1145, analyze the data across multiple time resolutions, or intervals. In other embodiments, the pre-analysis module 1165 can also be configured to prepare the data required to be included in standard reports requested by executive management of a production or manufacturing facility. The pre-analysis module 1165 can continuously run calculations and analysis on the data so that when a report is requested by the user, the data is ready to report almost instantaneously. The back-end processing by the pre-analysis module 1165 reduces the amount of time that a user has to wait in order to view a report. The back-end processing by the pre-analysis module 1165 also enables the display of real-time data that is updated continuously.

In some embodiments, the alert module 1170 can be configured to, for example, upon execution by the processor 1145, generate alerts to be sent to a user when an alert condition is met by the gathered data. Although the alert module 1170 has been illustrated as a component of the report center server 1110, the alert module 1170 can also be included in the data warehouse server 1105 and/or the network module 125.

As illustrated in FIG. 11, the client report interface 115 can include a user interface 1175, a processor 1180 and a memory 1185. As indicated by an arrow pointing from the report center server 1110 to and from the user interface 1175, the user interface 1175 is the interface by which the user interacts with the system 100. In some embodiments, the user interface 1175 is a web-based user interface, comprising a web site accessed by a web browser. In other embodiments, the user interface 1175 can comprise a wide variety of user interfaces, such as graphical user interfaces (GUIs), text-based interfaces, or any other interface capable of being utilized to transmit requests and receive responses from data center 110. The user interface 1175 can be configured to accept input and provide output by generating web pages that are transmitted via the Internet and viewed by a user on a secure website accessed via a web browser. In some embodiments, the client report interface 115 comprises a display device, such as a monitor, that allows the visual presentation of data, such as the monitored data describe herein, to a user. The client report interface 115 can comprise one or more input devices, such as a keyboard and/or cursor control (e.g., a mouse). In some embodiments, the web pages generated by the user interface 1175 can comprise GUIs that accept input from the one or more input devices and provide graphical output (e.g., charts, graphical tickers) of monitored data from the data center 110 on the display device.

In some embodiments, the processor 1180 can comprise a general or a special purpose microprocessor. The processor 1180 can comprise an application-specific integrated circuit (ASIC) or one or more modules configured to execute on one or more processors. The processor 1180 can communicate with the memory 1185 to retrieve and/or store data and/or program instructions for software and/or hardware. The memory 1185 can include RAM for temporary storage of information and/or ROM for permanent storage of information. In some embodiments, the memory 1185 can comprise a mass storage device, such as one or more hard drives, diskettes, and/or optical storage devices.

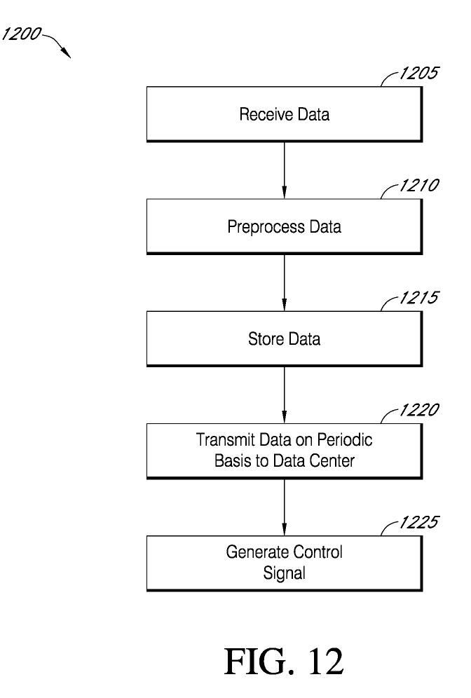

FIG. 12 illustrates a flowchart of an exemplary embodiment of a data gathering process 1200 executable by the network module 125. At Block 1205, the network module 125 gathers data from the various input sources of the energy consuming facility 105. For example, the PLC 1015 can continuously gather data from the input sources associated with the modules illustrated in FIGS. 2-9 at any frequency, for example but without limitation, every one half second, every second, every 5 seconds, every 10 seconds, once per minute etc. In some embodiments, the PLC 1015 can comprise multiple distributed PLCs. The PLC 1015 can temporarily store the data in a local memory and/or in a data structure, such as a stack. Also at Block 1205, the computing device 1045 queries the PLC 1015 at a defined interval (e.g., one minute) and receives all the data accumulated by the PLC 1015 during the prior defined interval. The transfer of data from the PLC 1015 to the computing device 1045 can occur over a local ethernet network, for example.

At Block 1210, the computing device 1045 preprocesses the data. The preprocessing of data can comprise transforming the data into a database format, organizing the data, and/or performing time correction of the data. In some embodiments, the data is transformed into a database format designed for the retrieval and management of data in a relational database system, such as Sybase, CodeBase, MySQL, Oracle or the like. The organization of the data can include organizing the data into blocks according to time entry, organizing the data into blocks according to the modules the data was received from, and/or organizing the data according to a structure custom to each facility and dependent on controls data being collected.

In some embodiments, the data is time-stamped based on Coordinated Universal Time (UTC), or Greenwich Mean Time (GMT). Use of UTC can be used to avoid problems performing time calculations during the one hour switch into and out of daylight saving time. However, if a company has facilities in various locations around the country or around the world, the sun can have a dramatic impact on the monitored data. If a national or global company desires to compare trends between facilities located in different time zones or at different longitudinal coordinates, there can be certain trends that do not manifest themselves when comparing reports of monitored data time-stamped according to UTC due to the effect of the sun. Accordingly, in some embodiments, the data can be time-stamped according to local time in addition to, or instead of, UTC time in order to allow for more accurate trend comparison between facilities.

At Block 1215, the computing device 1045 stores the data in local memory storage. In some embodiments, the storage of data in local memory serves as a short-term data backup in the case of a loss of network connection or a power outage. The data can be stored in local memory until the local memory storage reaches its storage capacity, at which point the old data in the local memory is replaced with new data. In other embodiments, the data can be stored on a mass storage device, such as a hard drive, diskette, and/or optical storage device.

At Block 1220, the network communication device 1050 transmits the data to the data center 110. In some embodiments, the data transmitted comprises the data accumulated by the computing device 1045 since the last data transmission. The transmission of data can occur at a predefined interval (e.g., every 60 seconds). In some embodiments, the computing device 1045 performs a database connection to the data center 110 and issues SQL INSERT statements to place the latest PLC data into a raw data table in the memory 1120 of the data center 110. In some embodiments, the data includes one or more of the following: an input code, facility identification, input source identification, instantaneous value, cumulative value, local time stamps, UTC time stamps, quality code, block identification, product identification, status information, and the like.

At Block 1225, the PLC 1015 generates control signals to output to the energy consuming facility based on the data received. In some embodiments, the PLC 1015 generates the control signals directly based upon initial receipt of the data. In other embodiments, the computing device 1045 directs the PLC 1015 to generate the control signals after preprocessing of the data. In yet other embodiments, the data center 110 initiates generation of the control signals after further processing and analysis of the data. In still other embodiments, generation of the control signals can be initiated by the user via the client report interface 115.

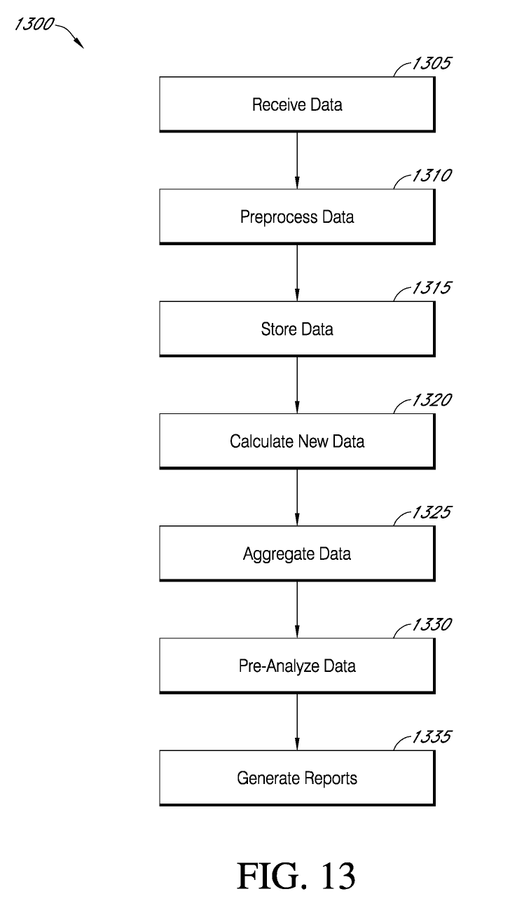

FIG. 13 is a flowchart 1300 illustrating an embodiment of the overall flow of data within the data center 110. At Block 1305, the data warehouse server 1105 receives data from one or more exchange point modules of one or more plants or facilities. In some embodiments, the data is received by the data warehouse server 1105 at defined intervals. The data can be received by the data warehouse server 1105 from multiple facilities over a secure communications network (e.g., a virtual private network). Also at Block 1305, the processor 1115 temporarily stores the data in local temporary storage (e.g., internal memory tables) for further processing.

At Block 1310, the processor 1115 preprocesses the data. In some embodiments, preprocessing of the data comprises organizing the data by enterprise and facility. For example, a separate server of the data center 110 can be dedicated to each separate enterprise. The preprocessing can also include validation of the data. In some embodiments, preprocessing can include adjusting the time stamp to reflect local time in addition to UTC time, or vice-versa, for the reasons discussed above.

At Block 1315, the processor 1115 permanently stores the preprocessed data on disk storage devices. At Block 1320, the processor 1115 calculates new data based on the application of predetermined formulas. In some embodiments, the new calculated data corresponds to data commonly requested by management personnel of energy consuming facilities. In some embodiments, some of the calculated data must be validated before being stored permanently. At Block 1325, the processor aggregates the data into blocks corresponding to a defined interval. For example, the data can be aggregated into quarter-hourly (15-minute) blocks, hour blocks, day blocks, week blocks, month blocks, and the like. Also at Block 1325, the data warehouse server 1105 transmits the aggregated data (e.g., via network communication device 1125) to the report center server 1110 and the processor 1145 stores the aggregated data in memory 1150. In some embodiments, some or all of the aggregated data remains stored on the data warehouse server 1105 and can be accessed by the report center server 1110.

At Block 1335, the processor 1145 pre-analyzes the data at multiple resolutions and prepares the data for reporting to the client report interface 115. For example, with reference to the data from the refrigeration module 130, the processor 1145 can take the data received from the compressor sensor 325 monitored by the refrigeration systems module 130 and generate a data point for the amount of electricity consumed by the compressor for each minute and store these data points in a preanalyzed file. The processor 1145 can then create additional preanalyzed files for other resolutions, including, for example but without limitation, preanalyzed files having one data point for each hour, day, week, month, year, and/or any other time resolution.

These preanalyzed files can then be used to generate reports or charts requested by a user. For example, if a manager or other user wants to see a report reflecting or based on the amount of electricity consumed by the compressor for single particular day, the user can request a report for the desired day. In response, the processor 1145 can provide the preanalyzed data file having the compressor data, processed to have one data point for each minute. The user may then decide to request a report showing the electricity consumed by the compressor for an entire year. As such, the processor can forward the preanalyzed data file containing the electricity used by the compressor with a single data point for each day.

The client side computer can then plot the data through the client report interface 115 to thereby generate a “report”. The weekly, monthly, and or other reports can also be displayed using the same or similar technique. Using such techniques, the client side computer operating as the client report interface 115 can be provided with preanalyzed data files that contain a reasonable number of data points for visualizing the data corresponding to the time span requested by the user. In both of the above examples, the processor 1145 provides the client side computer with files containing only a few hundred data points. As such, the transmission of the preanalyzed data files can be transmitted quickly over a network, such as the internet because the files are formed before the user requests and file and because the files are relatively small. Of course, as network speeds increase over time, due to new network communication technology, the processor 1145 can be configured to generate fewer preanalyzed data files so as to lower memory storage usage and still be able to transmit the files quickly over a network.

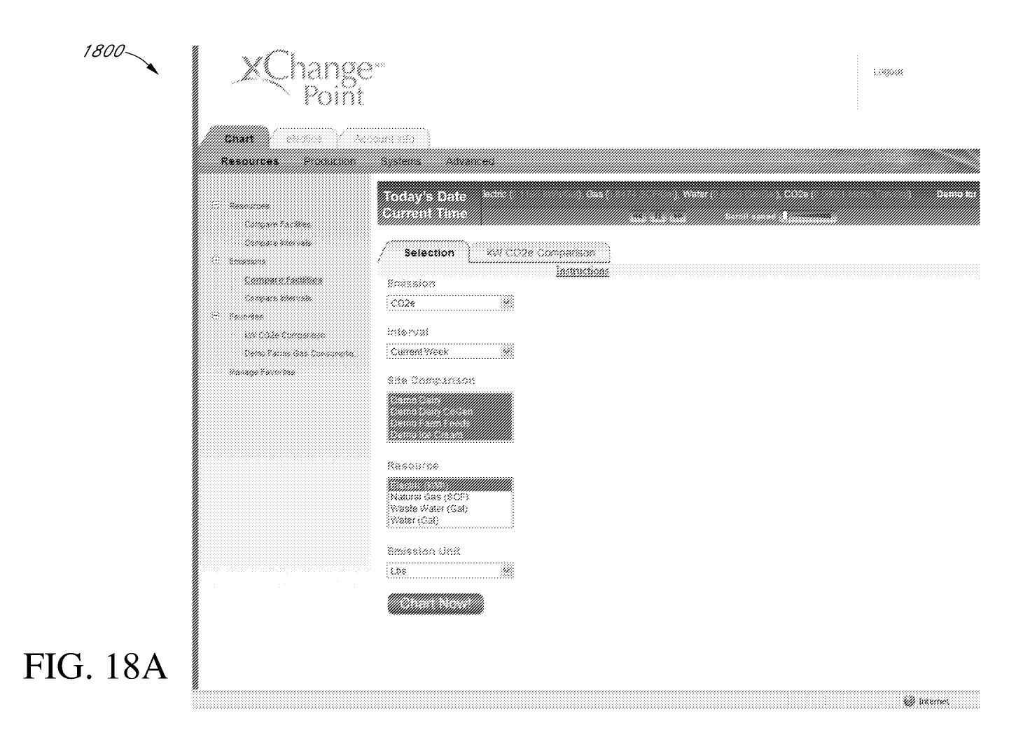

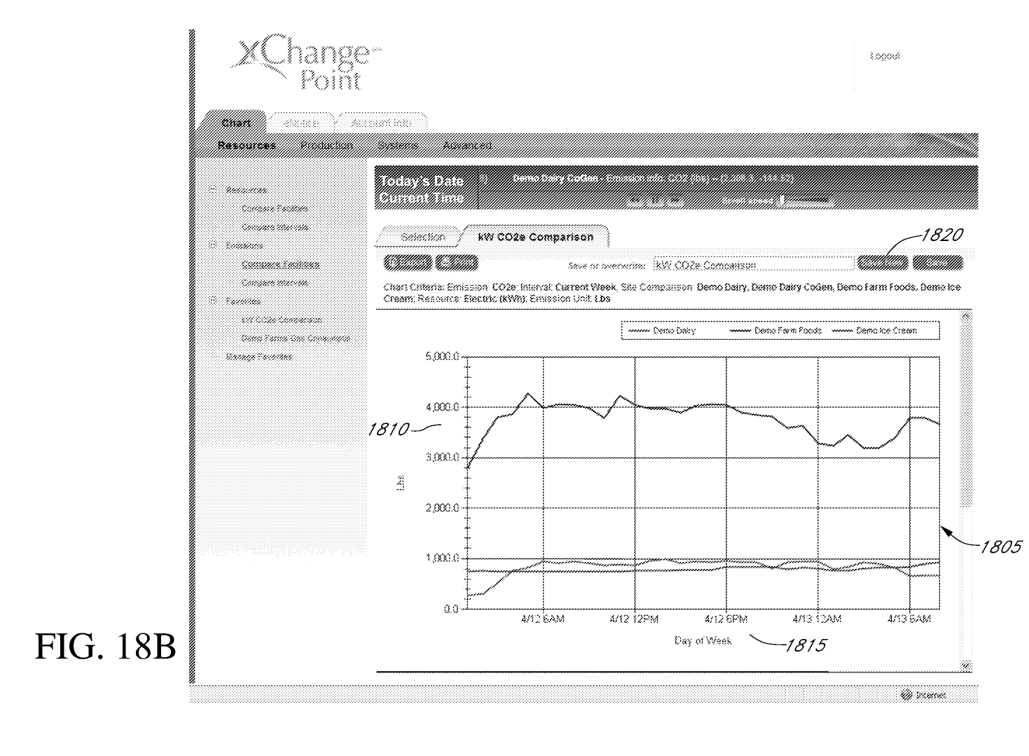

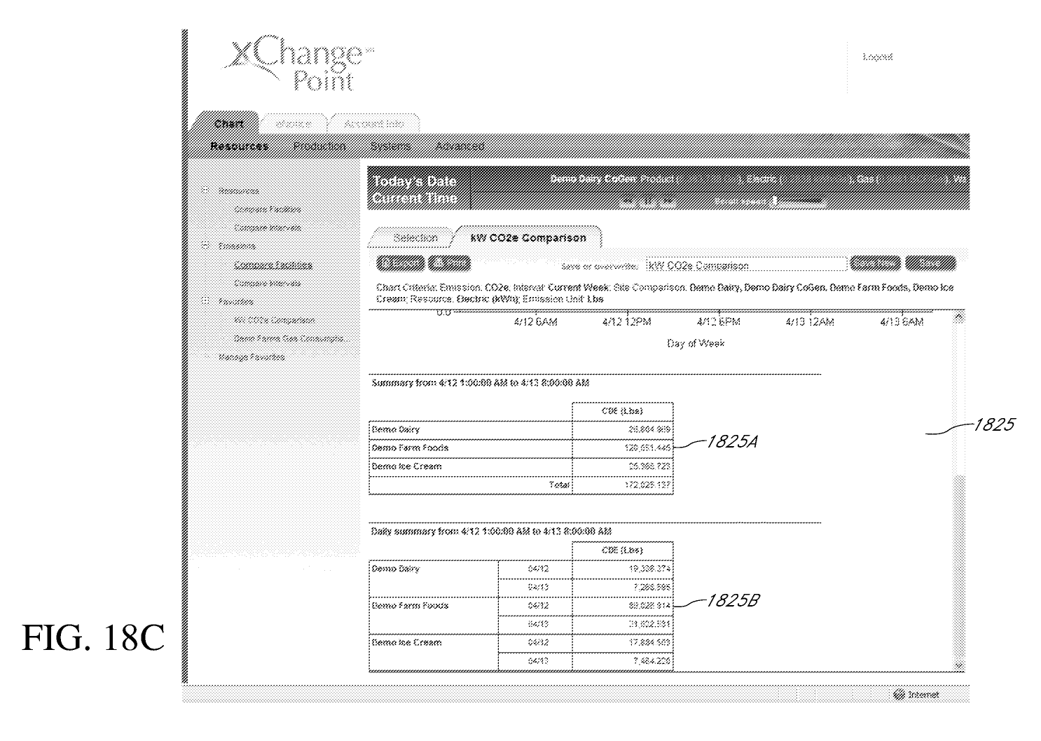

As another example, the processor 1145 can generate a data point representing the number of pounds of carbon dioxide equivalent (CO2e) emitted by a facility each minute, hour, day, week, month, year, and/or any other time resolution. FIGS. 18B and 18C (described in further detail below) illustrate an exemplary chart and summary table using the weekly and daily values of CO2e generated for a specific week requested by the user. It should be appreciated that the processor 1145 can generate a data point at multiple time resolutions for any of the individual input sources of the modules of FIGS. 2-9. The processor 1145 can also generate a data point at multiple time resolutions for any overall consumption or emission data for a module, facility or enterprise, such as total electricity consumption, total natural gas consumption, total water consumption, total sulfur dioxide emission, total carbon dioxide emission, total methane emission, and the like. Some of such total consumption or emission data can be calculated from calculations performed on one or more of a plurality of preanalyzed data files note above.

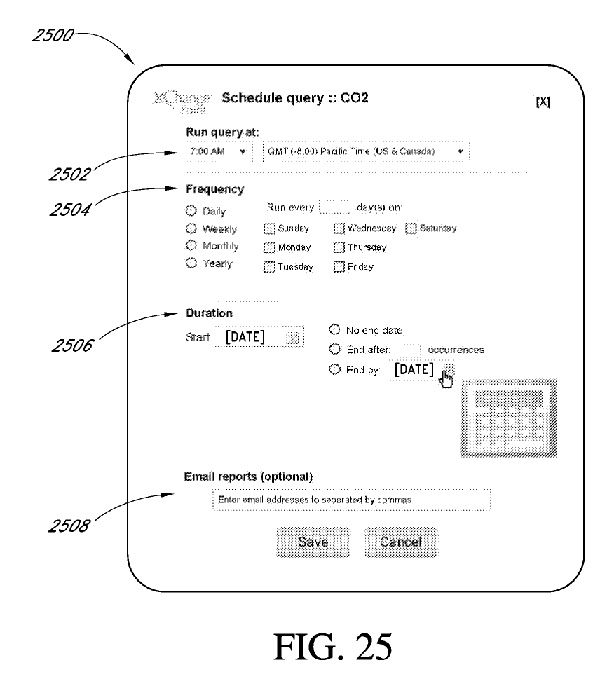

At Block 1335, the processor 1145 generates reports of the analyzed data and outputs the reports to the client report interface 115. The reports can be generated automatically (e.g., an alert or a ticker display) or upon request by a user. Additionally, as described below in greater detail with reference to FIG. 25, the system 100 can be configured to allow a user to schedule reports to be run with predetermined parameters end or at predetermined intervals. Users can also choose to have such reports delivered in a variety of ways to the user.

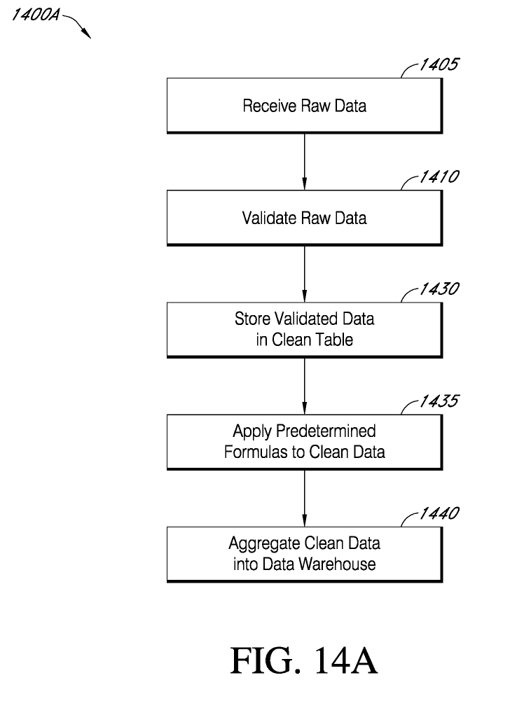

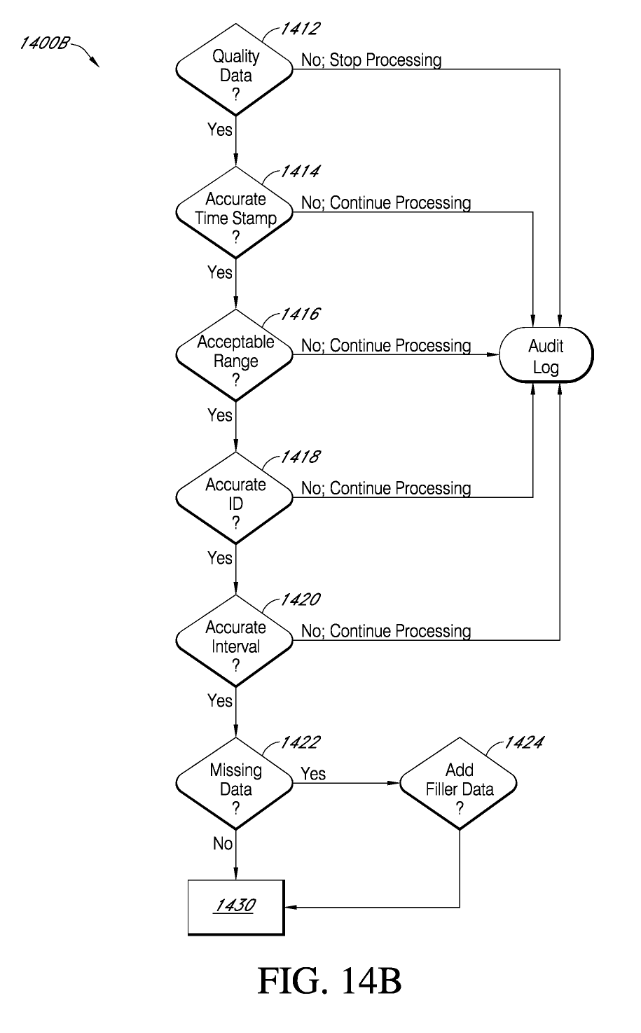

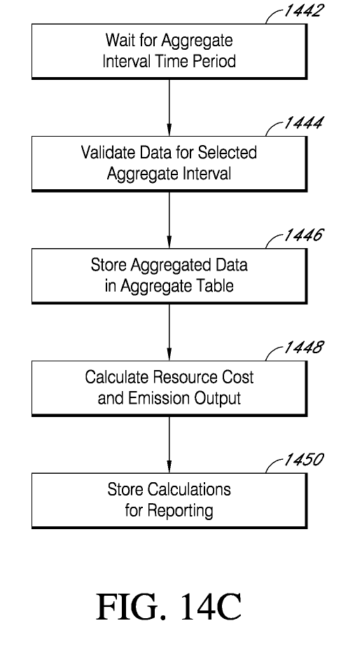

FIG. 14A illustrates a flowchart of an embodiment of an overall data analysis process 1400A. In some embodiments, the data analysis process 1400A is an iterative process that runs continuously at one or more defined intervals and processes the accumulated data received by the data warehouse server 1105 during the one or more defined intervals. At Block 1405, the data warehouse server 1105 receives “raw” data (e.g., via network communication device 1125) and stores it in a “raw” table in memory 1120. In some embodiments, the raw data can be received from the computing device 1045 of the network module 125. The raw data can comprise resource usage or other data received by the PLC 1015 from the various input sources of an energy consuming facility.

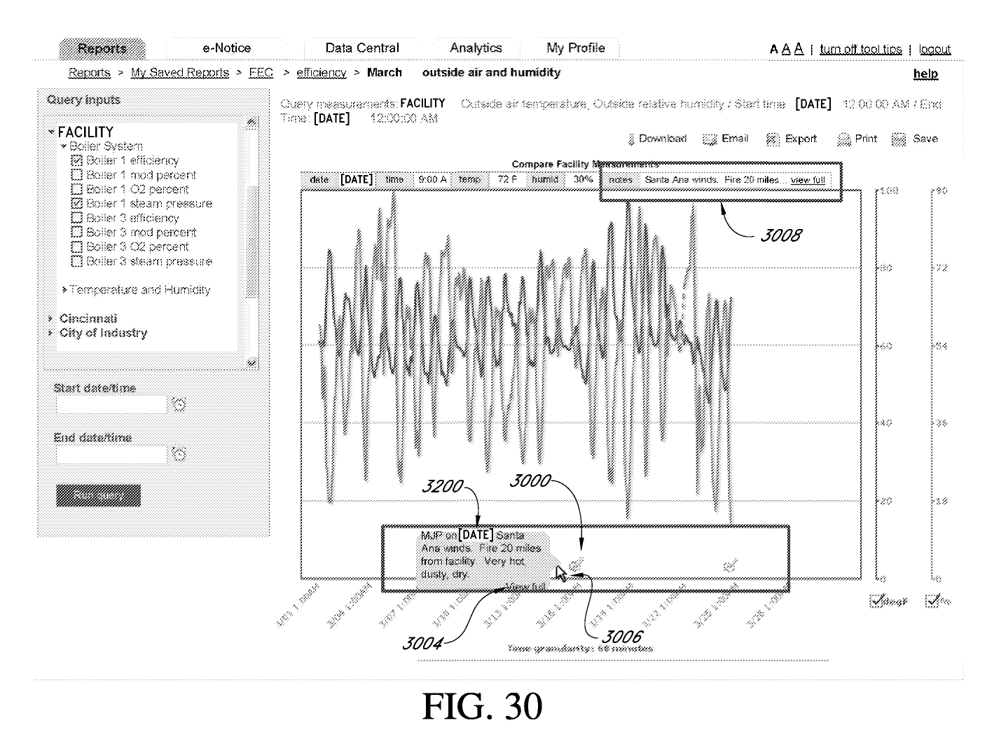

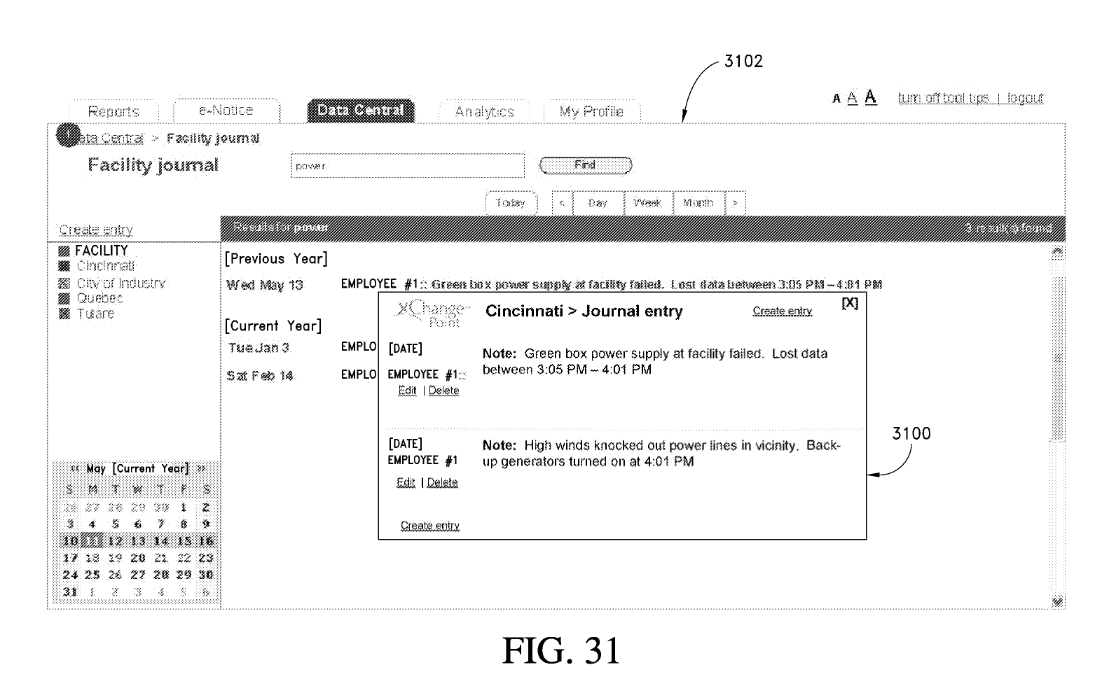

In other embodiments, raw data can be received via a manual human entry process. For example, historical resource usage data, production data, event data, and/or data that is not directly measured, such as waste water, can be inserted by a human operator on a web page via the client report interface 115. In yet other embodiments, raw data can be received via a manual File Transfer Protocol (FTP) process. For example, historical resource usage information from a utility company can be uploaded to the data center 110 via the client report interface 115 using a secure website. In still other embodiments, raw data can be received via an Enterprise Resource Planning (ERP) process. Some options for manually inputting relevant data is described below with reference to FIGS. 30 and 31.

At Block 1410, the data warehouse server 1105 validates the raw data according to specified rules to determine whether or not to continue processing the data. At Block 1430, the data warehouse server 1105 stores the validated data in a “clean” table in memory 1120. At Block 1435, the data warehouse server 1105 applies predetermined formulas to the “clean” data in order to generate new calculated data. At Block 1440, the data warehouse server 1105 aggregates all the clean data together for a defined interval into an aggregated table in memory 1120.

FIG. 14B illustrates a flowchart of an embodiment of a validation process 1400B. In some embodiments, the validation process 1400B can occur at Block 1410 of the data analysis process 1400A, illustrated in FIG. 14A. The validation process 1400B can comprise the application of validation rules against each data entry in the raw memory table. In some embodiments, each validation rule can be applied to the entire set of data in the raw memory table at the same time, instead of one entry at a time. In some embodiments, each validation rule is defined as a warning-level rule or an error-level rule. If at any point in the validation process 1400B, the data is deemed invalid based on a specified rule, a failure entry can be created in an audit log table in memory 1120 for later analysis. In some embodiments, failure to meet an error-level rule can prevent data from being processed any further or being stored in the clean memory table.

The validation process 1400B starts with decision block 1412, which determines whether the data received is of sufficient quality to be processed. In some embodiments, bad quality can be indicative of a device failure or a bad sensor. If the data is not of sufficient quality, an error-level failure entry will be created in an audit log table in memory 1120 and the data entry is not processed any further.

The validation process 1400B then proceeds to decision block 1414, which determines whether the data includes an accurate time stamp. If the data includes a time stamp that is in the future or too far in the past (which can be a configurable value), the data is deemed invalid and an error-level failure entry is generated in the audit log table. In some embodiments, the data will still continue to be processed if it fails this validation rule.

The validation process 1400B continues on to decision block 1416. Decision block 1416 determines whether the value of the data is within an acceptable range defined for the particular input source that generated the data. If the value is outside the acceptable range, the data is still valid but a warning-level failure entry is generated in the audit log table for later analysis. The validation process 1400B continues on to decision block 1418, which determines whether the data has any identification problems. Identification problems can occur, for example, if an identification variable is missing or if the combination of the input source identification and the facility identification associated with the data does not match a reference map or list stored in memory 1120. If the data does have identification problems, the data is still valid but a warning is generated in the audit log table.

The validation process 1400B continues on to decision block 1420, which determines whether the data falls within the appropriate time interval. In some embodiments, only one data entry is allowed for each facility ID/input source ID combination in the designated time interval. If more than one data entry exists for a particular facility ID/input source ID within the designated interval, then a warning-level failure entry is generated in the audit log table.

The validation process 1400B then continues on to decision block 1422, which determines whether or not there is any missing data within the designated time interval. If there is missing data within the designated time interval, then the validation process 1400B proceeds to decision block 1424, which determines whether filler data can be inserted to fill in the missing data. In some embodiments, filler data can be inserted for a missing or invalid data entry if two good data entries arrive within a maximum predefined time interval, such as 900 seconds (15 minutes). If two good data entries corresponding to a particular facility ID/input source ID combination arrive within the maximum predefined time interval, then the value of the prior good data entry will be inserted for the missing or invalid data entries. In other embodiments, the data can be interpolated using one or more adjacent data entries. If the second good data entry arrives more than the maximum specified length of time after the first good data entry, then no filler data is inserted to fill in the missing or invalid data entries. Whether or not filler data is inserted for the missing or invalid data entries, the validation process 1400B is completed and the data continues on to Block 1430 of FIG. 14A for further processing. It should be appreciated that the validation process 1400B can include other validation rules and decision blocks not identified.

FIG. 14C illustrates a flowchart of an exemplary embodiment of an aggregation process 1400C. The aggregation process 1400C begins at Block 1442. At Block 1442, the processor 1115 determines whether the appropriate time has lapsed since the last iteration of the aggregation process 1400C. In some embodiments, the aggregation process 1400C can repeat every fifteen minutes. In other embodiments, the aggregation process 1400C can repeat at any other designated interval. Once the designated time interval has elapsed, the aggregation process 1400C proceeds to Block 1444. At Block 1444, the processor 1115 validates the data from the clean memory table for the defined aggregate time interval. In some embodiments, validation comprises determining whether all the data for the desired aggregation interval has been received by the data warehouse server 1105. Validation can also include filling in missing or invalid data with filler data.

At Block 1446, the processor 1115 stores the aggregated data in an aggregate table in memory 1120. At Block 1448, the processor 1115 calculates a resource cost and emissions output for the data stored in the aggregate table. At Block 1450, the processor 1115 stores the calculated resource cost and emissions output in a resource usage table in memory 1120 for later reporting. It should be appreciated that the aggregation process 1400C can include aggregation of the data calculated by the data at Block 1435 of the data analysis process 1400A.

In some embodiments, the energy optimization system of FIG. 1 can be used to generate real-time reports to management personnel of a manufacturing or production facility. The real-time data can be accessed anywhere and anytime via a secure website operated and controlled by the report center server 1110. The real-time operations monitoring allows for an instant look into both high-level and individual systems' performance.

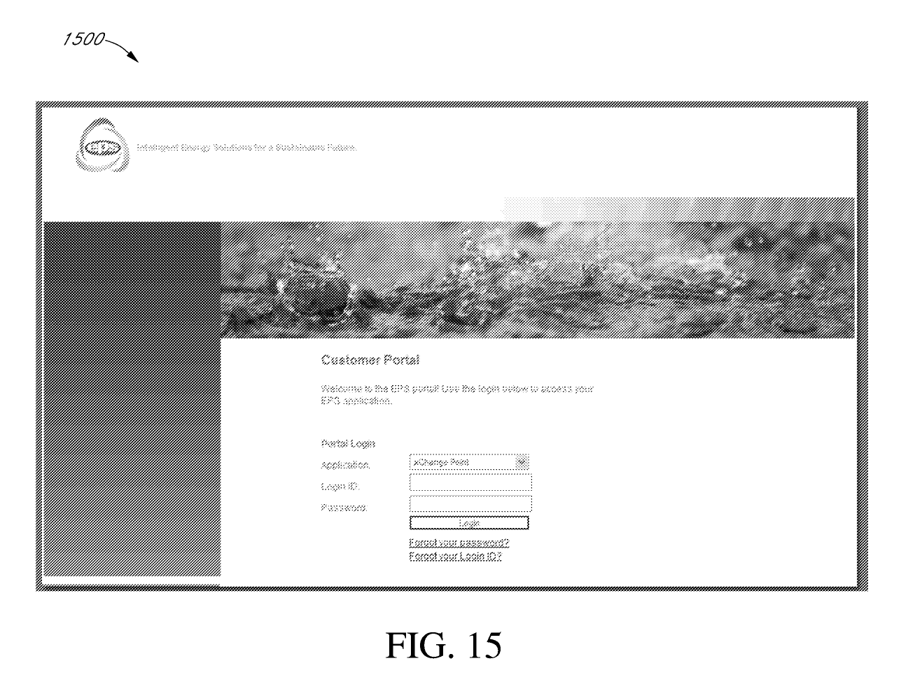

FIG. 15 illustrates an exemplary screen display of a customer portal login screen 1500 controlled and generated by the energy optimization system 100 of FIG. 1. The portal login screen 1500 can be displayed for example, on the user interface 1175 of FIG. 11. The portal login screen 1500 can be a web page as displayed by a web browser. As shown, access to the secure website at the client report interface 115 can require entry of a login ID and password. The login ID and password can prevent unauthorized access and can ensure that the reports will be generated from the data corresponding to the facilities associated with the user's login ID.

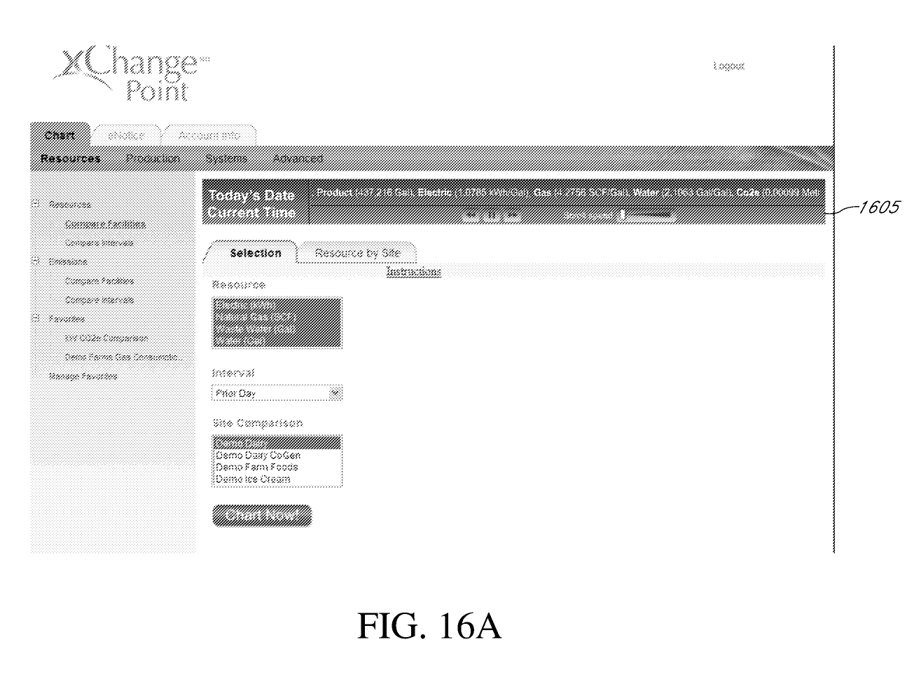

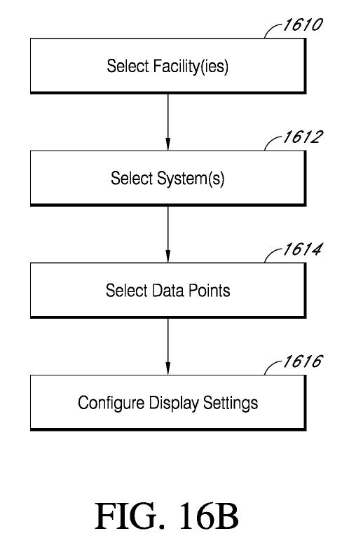

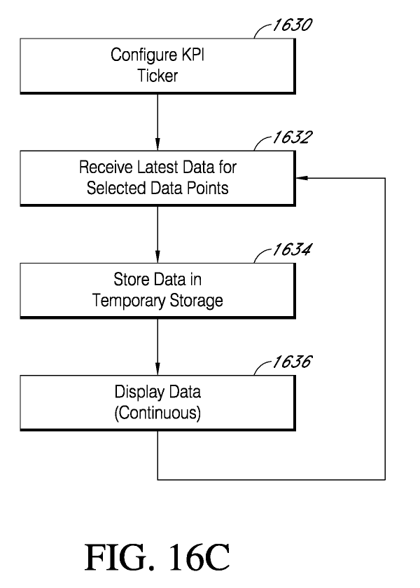

FIG. 16A illustrates an exemplary screen display of a graphical user interface of a scrolling display for providing automatic, continuous, real-time reporting of monitored data points. In some embodiments, the monitored data points are preselected by the user during a configuration process. The preselected monitored data points can be updated at any time. The data points can be updated, for example, based on user preferences or expansion of the data points being monitored. In some embodiments, the scrolling display tool comprises a KPI ticker tool 1605 that includes a scrolling display of real-time values associated with energy consumption systems being monitored at one or more facilities.

The KPI ticker tool 1605 can display total cumulative values for a defined interval, such as total electricity consumption for the current month, or real-time values of individual input sources, such as the current discharge pressure of a compressor of a refrigeration system. In some embodiments, the KPI ticker tool 1605 automatically displays upon login by the user at the customer portal login screen of FIG. 15. As shown, the KPI ticker tool 1605 includes buttons to rewind, pause, or fast-forward the scrolling display, as well as a button to adjust the scroll speed of the display. The KPI ticker tool 1605 can provide automatic real-time alerts to management personnel to enable them to quickly take action on critical elements. The KPI ticker tool 1605 can also provide an executive high-level overview of the current operations of the monitored systems.

FIG. 16B illustrates a flowchart of an exemplary embodiment of a configuration process for configuring the KPI ticker tool 1605. Configuration can occur at the first login by the user to the client report interface 115 and/or at any other time. At Block 1610, the user selects the facility or facilities to be monitored. At Block 1612, the user selects the system to be displayed on the KPI ticker tool 1605 (e.g., the refrigeration system or the boiler system). At Block 1614, the user selects the data points to be displayed for the selected system. The data points can include emissions data, resource usage data, production data, and/or individual source data. At Block 1616, the user configures display settings for the KPI ticker tool 1605.

For example, the user can select high and low alert colors to be used for the values displayed. In some embodiments, the user can set high and low threshold values for each of the monitored data points. If the current value displayed is less than the low threshold, it can be displayed with a red color, for example, and if the current value displayed is greater than the high threshold, it can be displayed with a green color, for example. In some embodiments, the value displayed for a monitored data point can also include the delta change from a previous value. For example, if the value being displayed is a cumulative value for the current month, the KPI ticker tool 1605 can also display the difference in the value from the previous month or the current month last year. If the current value being displayed is a real-time value of a monitored data point, the KPI ticker tool 1605 can display the difference between the current value and the previously-updated value.

FIG. 16C illustrates a flowchart of an exemplary embodiment of an overall operation of a scrolling toolbar display, such as the KPI ticker tool 1605. At Block 1630, a user configures the KPI ticker tool, for example, as described above in connection with FIG. 16B. At Block 1632, the client report interface 110 receives the data from the data center 110 for the monitored data points selected by the user during configuration. In some embodiments, the data is received at predefined intervals, such as every fifteen minutes. At Block 1634, the client report interface 110 stores the data in memory (e.g., memory 1185). At Block 1636, the client report interface 110 continuously displays the data via the scrolling display graphical user interface (e.g., KPI ticker tool 1605). After the predefined interval has elapsed, updated data is received by the client report interface 110 for each of the monitored data points and the scrolling display is updated to reflect the real-time updated data received.

In some embodiments, real-time alerts can be generated by the energy optimization system 100. In some embodiments, certain real-time alerts are generated automatically without being preconfigured by the user. For example, an alert can be set to notify management personnel if data spikes over baseline levels on natural gas, water and/or electricity. In other embodiments, the user sets up alert definitions that define when an alert should be generated. For example, an alert can be set up to notify management personnel if water stops running in a boiler so that the gas can be turned off immediately. The real-time alerts can advantageously alert key management personnel as soon as a potential issue is identified by the system. In some embodiments, the user does not have to issue a query or continuously monitor the systems or their associated input sources in order to identify problems.

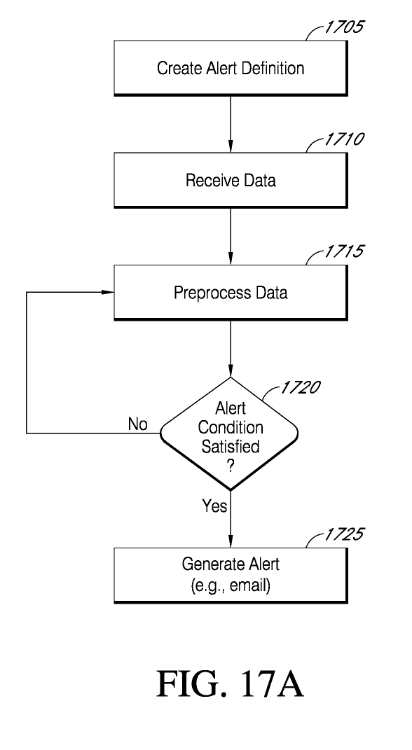

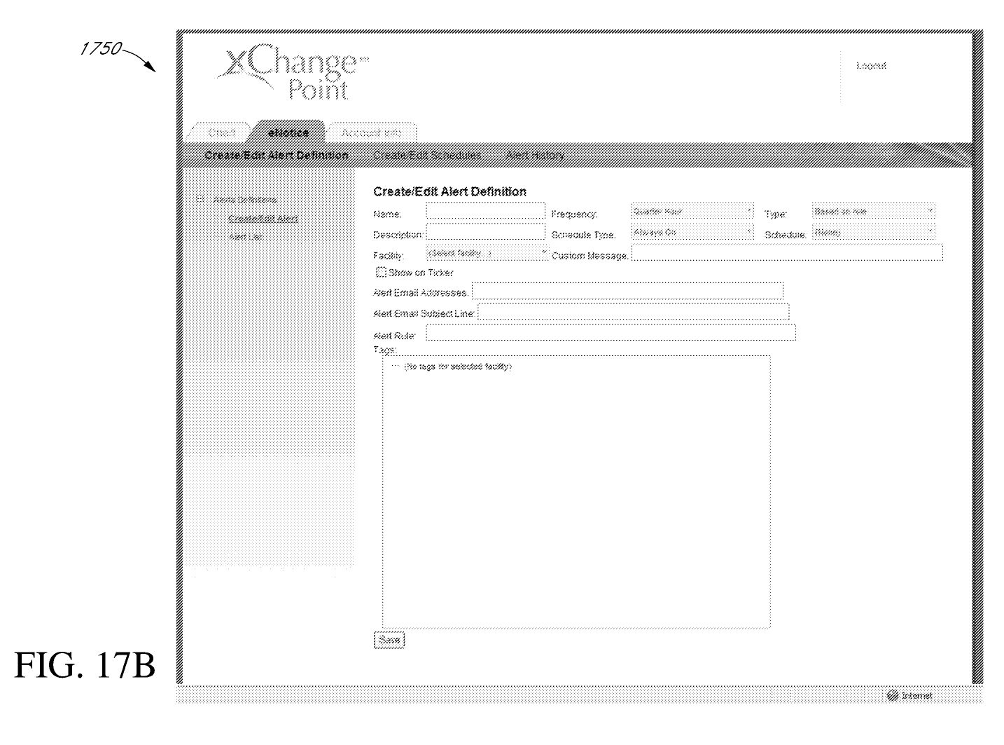

FIG. 17A illustrates a flowchart of an exemplary embodiment of an alert generation process 1700. At Block 1705, a user creates an alert definition using a graphical user interface tool (as shown in FIG. 17B). At Block 1710, the energy optimization system 100 receives data from one or more facilities. At Block 1715, the energy optimization system 100 preprocesses the data. At decision block 1720, the energy optimization system 100 determines whether the alert definition created by the user is satisfied. If the alert definition is not satisfied, then the process returns to preprocessing the data at Block 1715. If the alert definition is satisfied, an alert is generated at Block 1725 and sent to the user (e.g., via email). In addition to being sent to the user (e.g., via email), the alert can be displayed on the KPI ticker tool 1605 and/or stored in an alert history database that can be accessed via the client report interface 1110. As discussed above, an alert can be generated at any point during processing of the data. For example, an alert can be generated by the PLC 1015, by the computing device 1045, and/or by the data center 110.

FIG. 17B illustrates an exemplary screen display of a graphical user interface of an alert configuration tool 1750. As illustrated in FIG. 17B, the user can specify the frequency of the alert definition (e.g., quarter hour, hour, day, week), the type of alert (e.g., a rule-based alert or an alert if a value is missing), and the schedule for the alert (e.g., every day, every other day, weekends). In some embodiments, the user can also insert one or more email addresses of persons that should receive the alert notification. If the alert is rule-based, the user can also specify the rule that must be violated in order to generate the alert. In some embodiments, the user can select the specific sensors or meters to monitor for the alert definition. For example, if a particular sensor or meter is of critical importance, an alert can be set up to immediately notify the user if the alert definition is satisfied. As another example, an alert can be set up to monitor a piece of equipment that frequently breaks down or a sensor that frequently malfunctions. Selection can be made by command line or by graphical user interface objects, such as list boxes, drop down lists, check boxes and/or the like.

FIG. 18A illustrates a screen display of an exemplary embodiment of a graphical user interface of a chart generation tool 1800. To effectively manage energy consumption, management personnel can regularly chart monitored resources such as electricity, natural gas and water used on the production line at their plants. In some embodiments, management personnel can generate customized charts according to their desired preferences. For example, a company manager can generate a report comparing resource usage and/or emissions output data across all the company facilities in order to identify trends or to determine which facility to focus optimization efforts on. In some embodiments, the chart generation tool 1800 can include embedded code that provides functionality for generating overlay display objects in response to mouse-over events. For example, an overlay display object can be generated containing instructions for generating a report.

As shown, the chart generation tool can include selection fields for the following: emission (e.g., nitrous oxide, sulfur dioxide, carbon dioxide, and CO2e); time interval (current day, prior day, current week, prior week, current month, prior month, current year, prior year, and last six months); the facilities/sites to compare; the resources to compare; and the emission unit (e.g., lbs or metric tons). Selections can be made by command line or by graphical user interface objects, such as list boxes, drop down lists, check boxes and/or the like. The selections illustrated in FIG. 18A have been chosen to compare equivalent carbon dioxide (CO2e) values for all the highlighted facilities for the current week.

FIG. 18B is a screen display of a line chart 1805 generated by the selections made in FIG. 18A. As shown in FIG. 18B, the chart displays the CO2e values along the ordinate, or y-axis 1810, and the time along the abscissa, or x-axis 1815. The lines of data for the different facilities can be displayed using different colors and/or patterns. A legend can identify the color and/or pattern used for each facility. In other embodiments, the chart can be displayed using other types of chart formats (e.g., bar, area, and the like). It should be appreciated by one of ordinary skill in the art, that because the data has been pre-processed and pre-analyzed beforehand by the data center 110, the chart is generated almost instantaneously (e.g., in a matter of seconds). In some embodiments, the data is displayed at increments corresponding to the predefined aggregate interval (e.g., 15 minutes). For example, a data point is charted for each 15-minute interval along the x-axis. As further shown in FIG. 18B, the chart and its underlying selections can be saved as a “Favorite” chart to use in the future by clicking on the Save New button 1820.

FIG. 18C illustrates a screen display of an exemplary embodiment of a summary table 1825 accompanying the chart of FIG. 18B. The summary table 1825 includes a weekly summary 1825A and a daily summary 1825B. The cumulative summary lists the cumulative CO2e value for each facility for the current week. The daily summary table lists the cumulative CO2e value for each facility for each day of the current week. These cumulative weekly and daily values can be generated by and received from, for example, the pre-analysis module 1165 of the report center 1110. As shown in FIG. 18C, the reported data can be extracted by exporting or printing the data in order to preserve the data for later reference. In some embodiments, the data can be exported and saved in the following formats: XML, CSV, TIFF, PDF, Web Archive, Excel and/or the like.

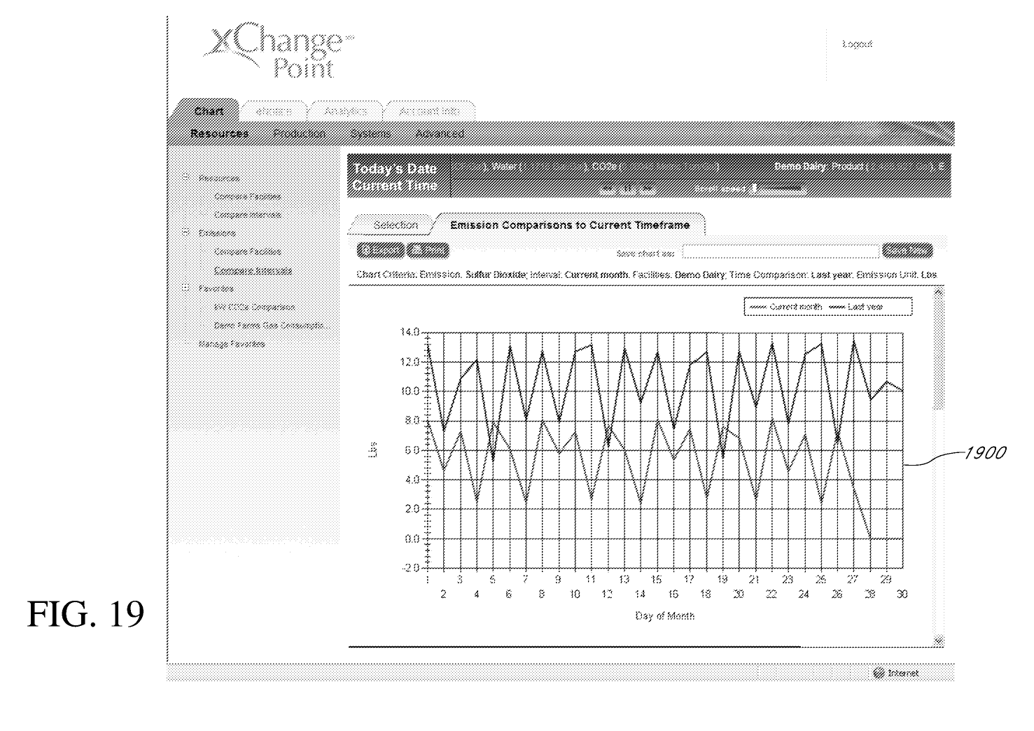

FIG. 19 illustrates a screen display of an exemplary embodiment of an interval comparison chart 1900. The interval comparison chart 1900 shows a comparison of sulfur dioxide emission by a dairy facility between the current month and the current month last year. This type of chart can be used to identify whether emissions have been successfully reduced by the energy optimization system 100.

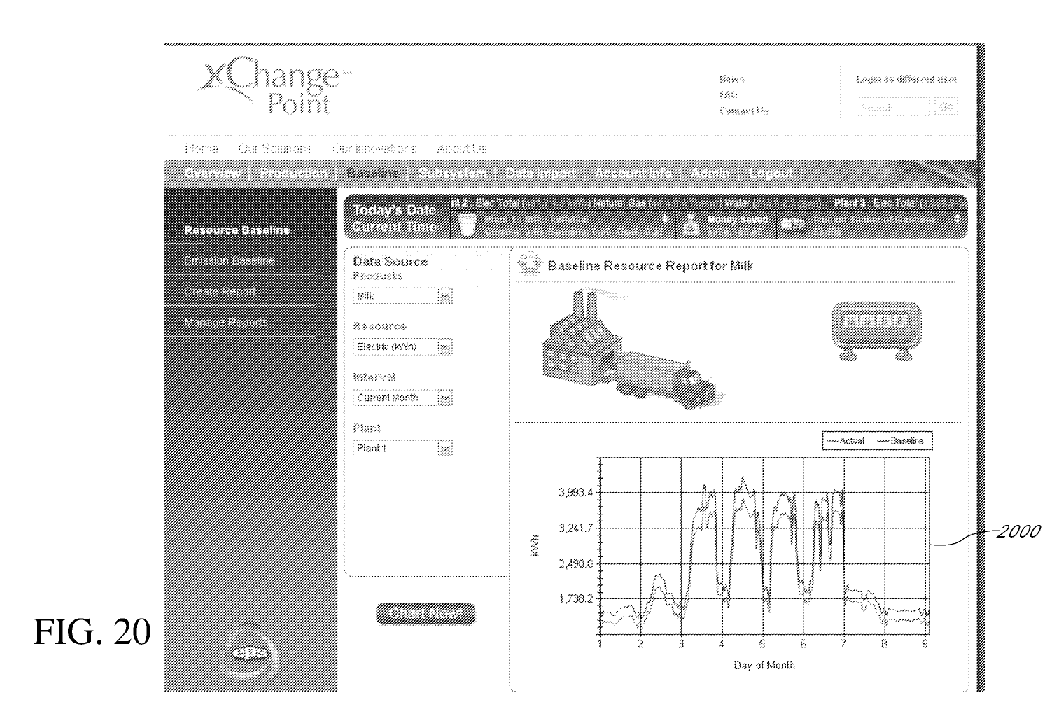

FIG. 20 illustrates a screen display of an exemplary embodiment of a baseline resource report chart 2000. The baseline resource report chart 2000 can be used, for example, to compare actual energy consumption required to produce a product with a predefined baseline. In some embodiments, the baseline can be defined by data from a previous time interval. In other embodiments, the baseline can be defined by the user as a target goal. This type of chart can assist management personnel in assessing whether a production facility is meeting its projected goals for reducing energy consumption or reducing greenhouse gas emissions.

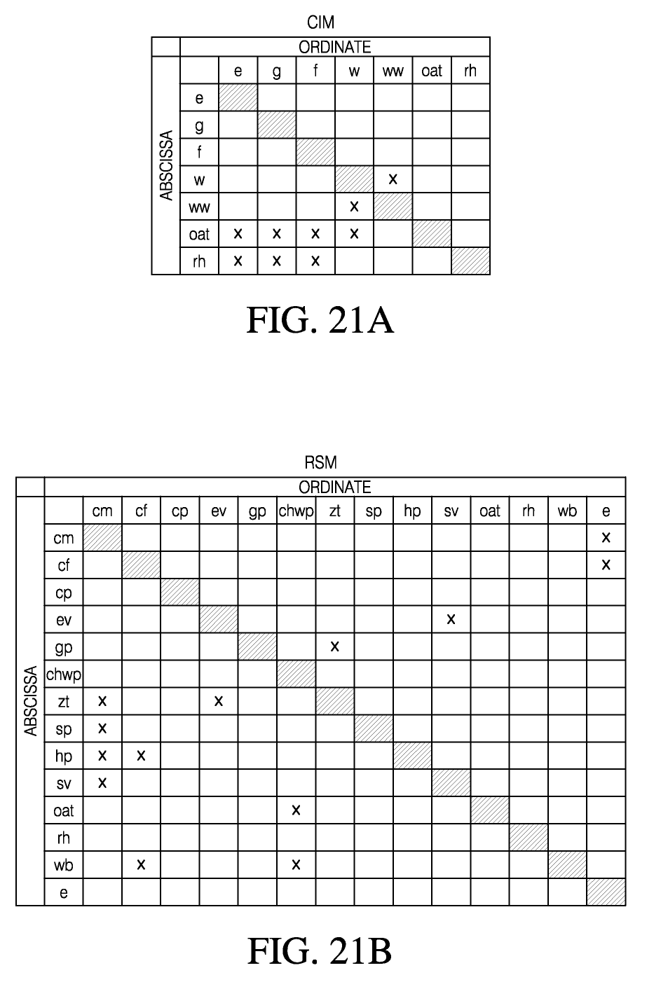

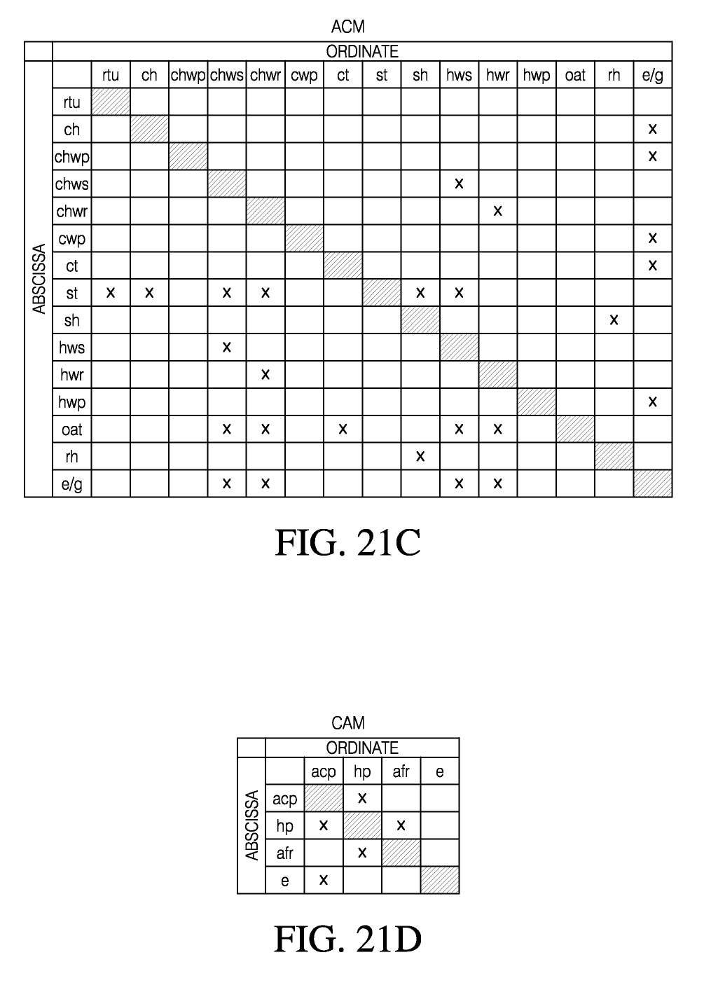

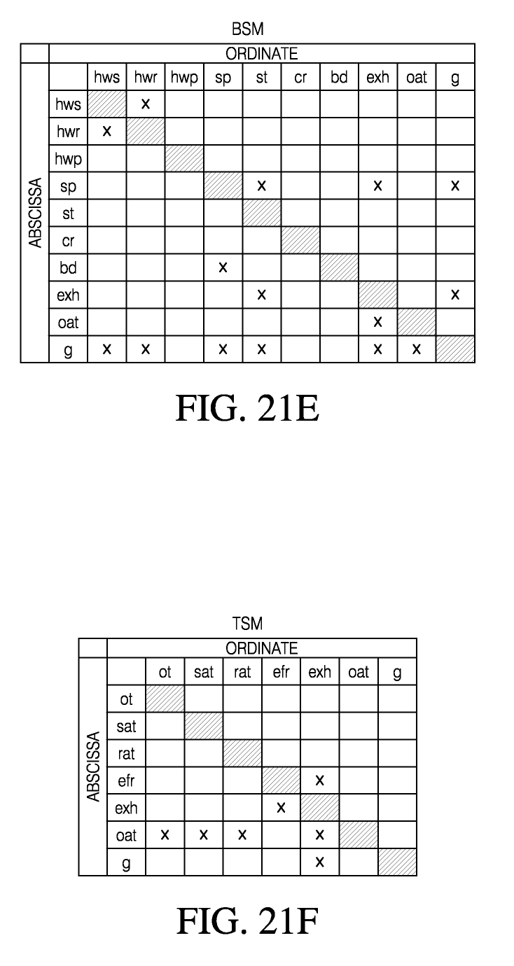

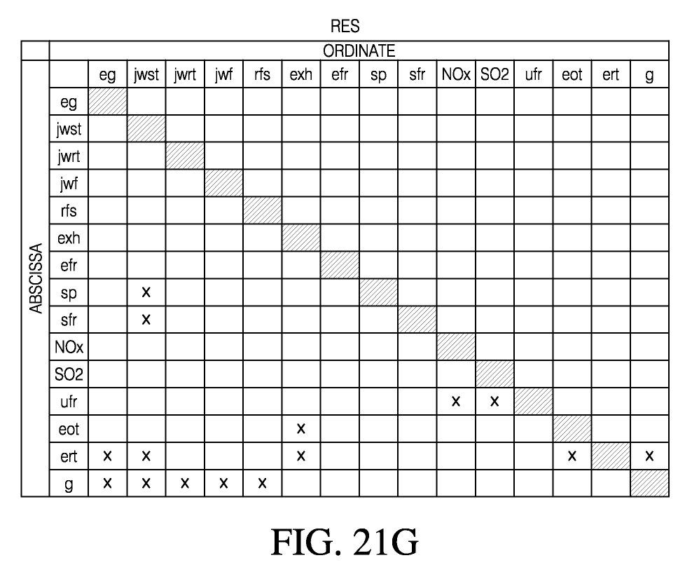

To maximize resource efficiency and energy savings, management personnel can dig deeper into the data by creating reports of individual input sources instead of overall energy consumption or emissions production. In some embodiments, a user may want to compare two or more input sources in order to determine any correlation trends. FIGS. 21A-21G illustrate grids of potential correlation reports that can be generated by the client report interface 115. For example, FIG. 21A lists the abbreviations for the various input sources of the CIM 200 illustrated in FIG. 2. As illustrated by the grid, a report can be generated comparing the data from the water (w) flow meter 230 with the wastewater (ww) input 235. Reports can also be generated comparing the data from the outside air temperature (oat) sensor 225 with data from the total electricity (e) meter 205, the total natural gas (g) meter 210, the alternate fuel (f) meter 215, and/or the water (w) flow meter 220. Reports can also be generated comparing the data from the relative humidity (rh) sensor with the total electricity (e) meter 205, the total natural gas (g) meter 210, the alternate fuel (f) meter 215.

FIG. 21B illustrates potential correlation reports for refrigeration systems module (RSM) 130. FIG. 21C illustrates potential correlation reports for HVAC module 135 (ACM). FIG. 21D illustrates potential correlation reports for compressed air module 140 (CAM). FIG. 21E illustrates potential correlation reports for boiler systems module (BSM) 145. FIG. 21F illustrates potential correlation reports for thermal systems module (TSM) 160. FIG. 21G illustrates potential correlation reports for renewable energy systems module (RES) 160.

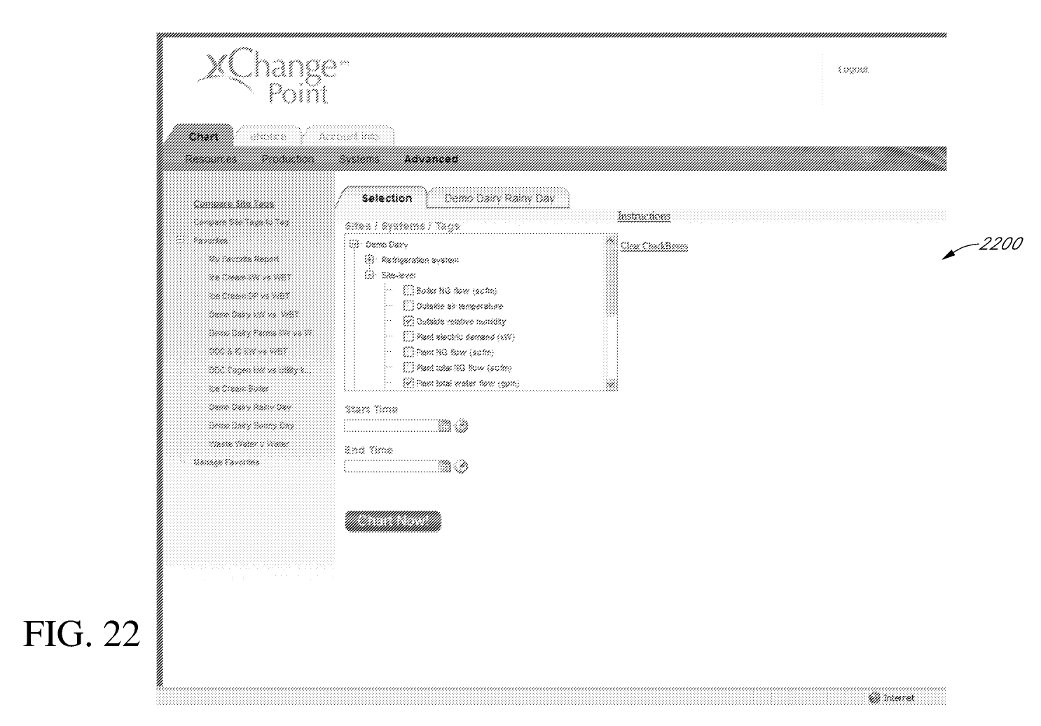

FIG. 22 illustrates a screen display of an exemplary embodiment of a graphical user interface tool 2200 for selecting input sources to compare in a report. In some embodiments, a user can select up to five input sources for comparison. Selection can be made by graphical user interface objects, such as drop-down lists and checkboxes. FIG. 22 illustrates the selection of the outside relative humidity sensor and the plant total water flow meter. As shown in FIG. 22, the user can input a start time and an end time for the report. In some embodiments, the selections can be stored as a “favorite” report.

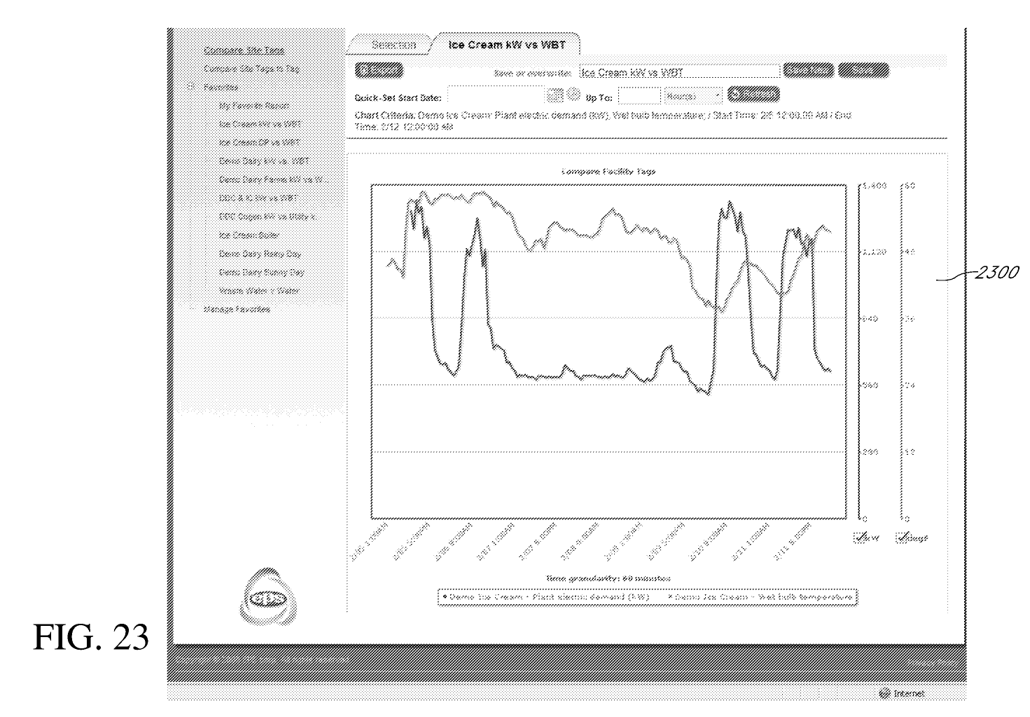

FIG. 23 illustrates a screen display of an exemplary correlation chart 2300 comparing plant electric demand and wet bulb temperature at an ice cream production facility. As shown, the correlation chart 2300 can include two separate scales for each of the input sources. The correlation chart 2300 includes data for one week with a time granularity of sixty minutes. If the graph appears too crowded or the user wants to view a single monitored data point, the user can uncheck the boxes beneath the scales to the right of the chart and the scale and its corresponding data will be removed from the chart. If the user wants to bring the data back, the user can re-check the box.

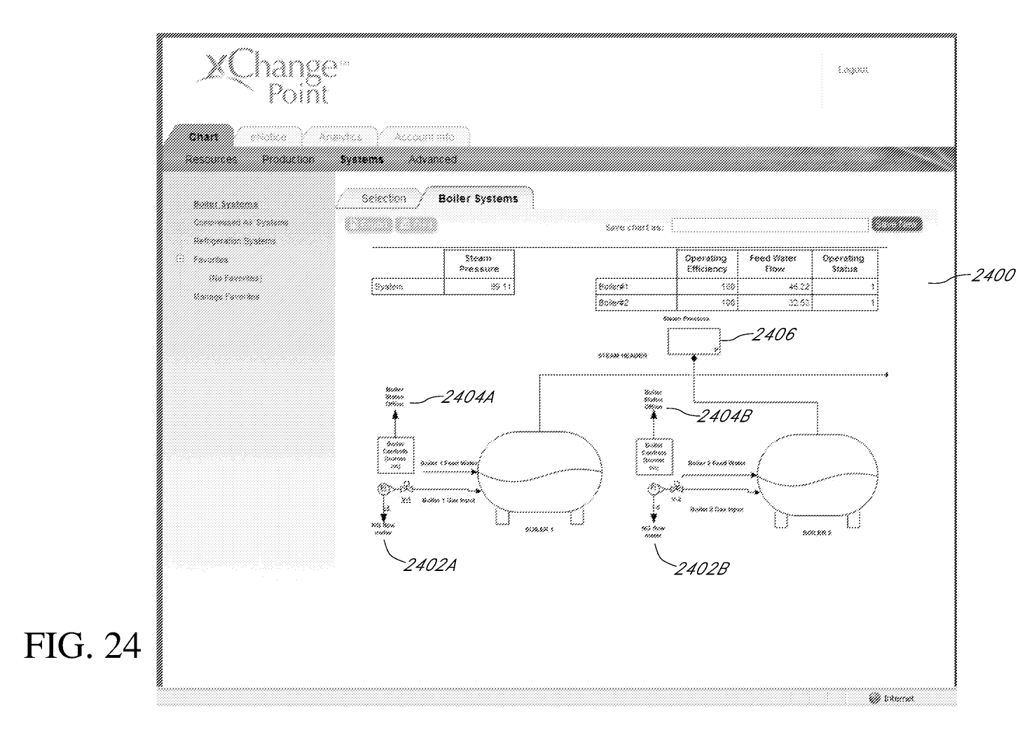

FIG. 24 illustrates a screen display of an exemplary graphical user interface of a module status report 2400. As shown, the module status report 2400 includes a systematic diagram of a boiler system and the input sources being used to monitor various data points. For example, the module status report 2400 includes a natural gas (NG) flow meter 2402A, 2402B for each of the boilers, a boiler status sensor 2404A, 2404B for each of the boilers, and a steam pressure sensor 2406. The module status report 2400 also includes tables displaying the current real-time values of the input sources of the boiler system. In some embodiments, a user can cause commands to be generated and sent to a facility by clicking on various graphical objects displayed on the graphical user interface.

With reference to FIG. 25, a user interface, such as the client report interface 115, can be configured to allow a user to schedule reports to be run with predetermined parameters and/or at predetermined intervals. For example, as illustrated in FIG. 25, such a user interface can generate report scheduler interface 2500, which can be in the form of a pop-up window, or any other type of window, text-based, or graphical user interface screen.

The interface 2500 can include a date input 2502, a frequency input 2504, a duration input 2506, as well as other inputs. The date input 2502 can be configured to allow a user to insert a generic date and/or time of day at which the intended report is scheduled to run. For example, as illustrated in the exemplary embodiment of FIG. 25, the date input 2502 includes a time of day selection field and can optionally include a date selection field for indicating the first date upon which the report should run. Optionally, as also illustrated in FIG. 25, the date input 2502 can include a field indicating the chosen time in Greenwich mean Time (GMT).

The frequency input 2504 can include an input area allowing the user to choose or manually input the frequency at which the report should be run. In the illustrated exemplary embodiment of FIG. 25, the frequency input 2504 includes choices such as daily, weekly, monthly, and yearly. However, other frequencies can also be used. Additionally, the frequency input 2504 also includes a day of week input area allowing the user to choose any day of the week upon which the report should be run. This embodiment also includes a field allowing a user to choose the number of days between each report.

The duration input 2506 is configured to allow a user to indicate how long, and thereby how many times, the scheduled report should be run. For example, the duration input 2506 can include a start date input portion and an end date input portion. In the illustrated embodiment, the end date input portion allows the user to choose “no end date”, thereby causing the report to be scheduled to repeat indefinitely. The end date input also includes options for allowing the user to indicate that the scheduled report should stop running after a specified number of reports have been generated or to end on a particular date.

As shown in FIG. 25, the interface 2500 can also include a delivery input 2508. The delivery input 2508 can be configured to allow the user to choose how the report should be delivered to the user. For example, the delivery input 2508 can be configured to allow a user to choose to receive the reports by e-mail, text message (SMS), regular mail, etc. Other delivery techniques can also be provided.

An aspect of at least one of the embodiments disclosed herein includes the realization that aberrations in data collected by the system 100 can be caused by events which are not detected by the instrumentation included in the system memory 100. For example, facility staff might accidentally crashed into a boiler with a forklift, damaging some equipment, and causing the boiler to operate inefficiently until the damage component is repaired. Data from the boiler systems module 145 may include an aberration showing a period of reduced efficiency on a certain date. However, the instrumentation included in the system 100 might not provide sufficient information to allow a user of the system 100 to conclude that the aberration in the data was caused by an accident. Thus, a user of the system 100 might incorrectly assume the aberration in the data is an opportunity for further optimization and thus waste valuable time in attempting to investigate the cause of the aberration by analyzing data from the system 100 and or through the client report interface 115.

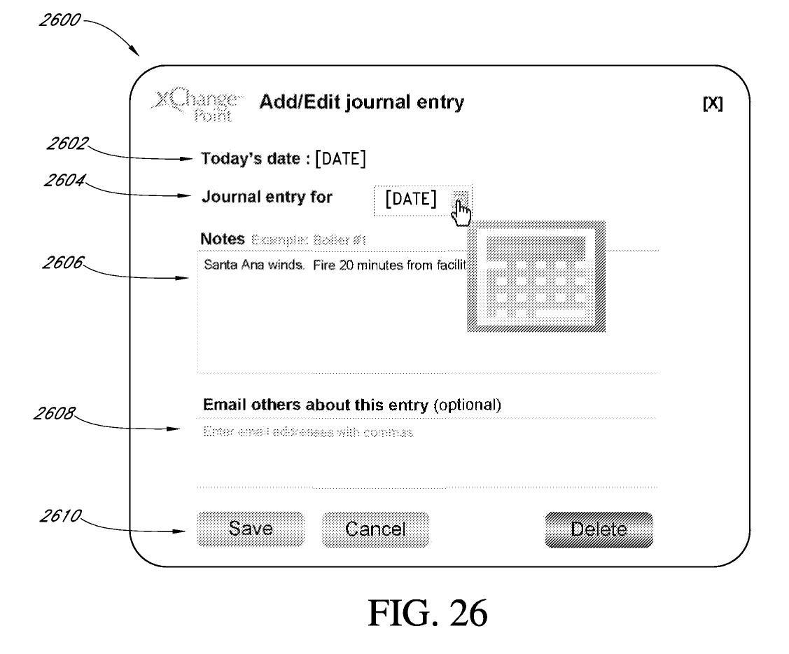

Thus, in some embodiments, the system 100 can include an events Journal module configured to allow users of the system 102 input descriptions of events, such as those that cannot be detected by the instrumentation included in the system 100. FIG. 26 includes an illustration of an exemplary events Journal interface 2600. The interface 2600 can be in the form of a pop-up window, text, graphical user interface, or any other type of interface.

As illustrated in FIG. 26, the interface 2600 can include a date input 2602 and even date input 2604 a description and put 2606 and a distribution input 2608. The date input 2602 can be configured to allow a user to input the current state. For example, the date input 2602 can be configured to allow a user to input a date upon which the journal entry is made. For example, a user may observe an event occurring on Monday but compose a journal entry on a different day. Optionally, the interface 2600 can be configured to automatically fill in the date input 2602 with the current state.

The event date input 2604 can be configured to allow user to input the date upon which the event occurred. In some embodiments, the event's date input 2604 can include a pop-up calendar allowing the user to choose the date of a graphical representation of a monthly or yearly calendar.

The description input 2606 can include a text input field allowing the user to manually enter a description of the event. In some embodiments, description input 2606 can include predetermined optional selections for indicating the type of event (e.g. power outage, scheduled maintenance, etc.), cause of the event (e.g., accident, weather, etc.) and/or other types of information. Such predetermined optional selection configurations can further simplify the organization and analysis of such events Journal entries. Optionally, the interface 2600 can also include a command input 2610 which can include one or more typical operation buttons, such as, for example but without limitation, save, cancel, delete, and/or other functions.

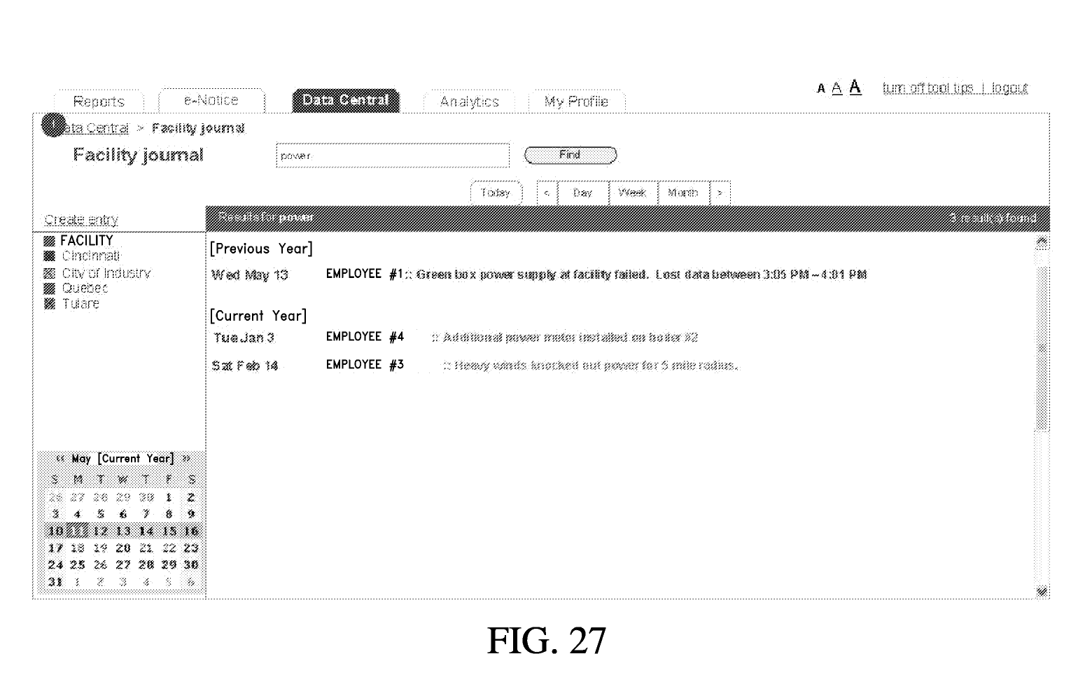

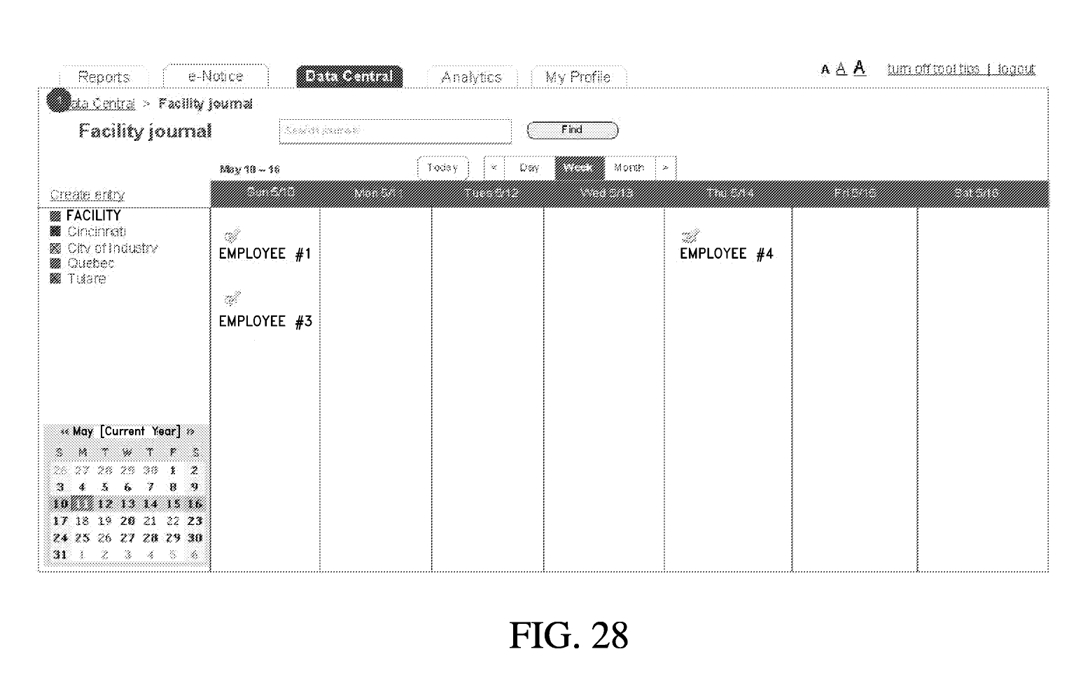

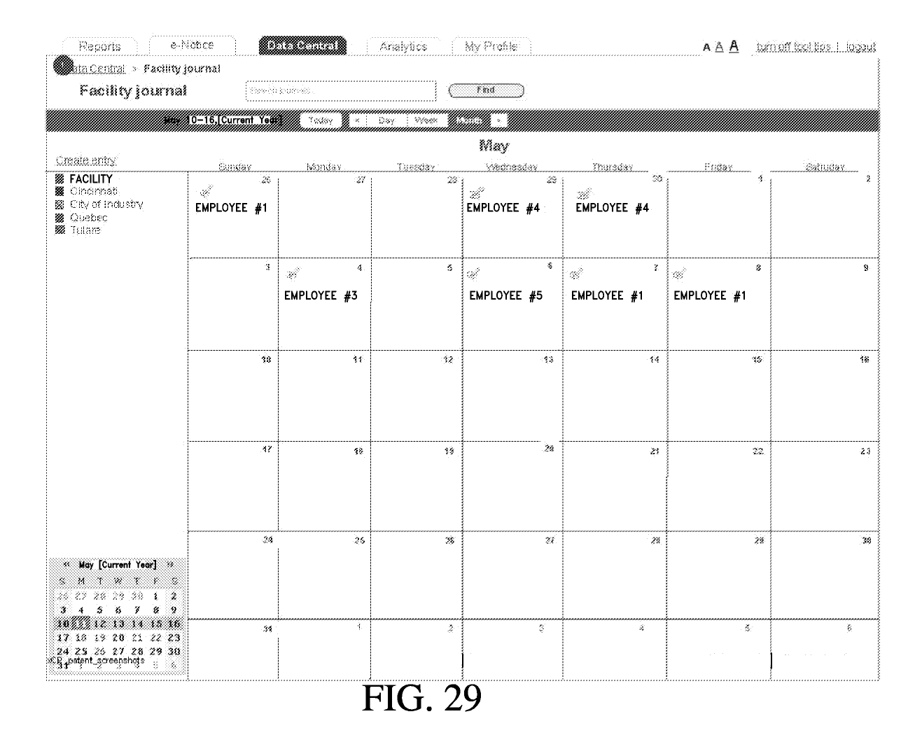

The system 100 can be configured to save such events Journal entries, such as that described above with reference to FIG. 26, an internal database. FIGS. 27-29 illustrate various non-limiting examples of configurations for displaying event journal entries that can be incorporated into the client report interface 115.

Another aspect of the least one of the embodiments disclosed herein includes the realization that with a collection of manually entered events, it can be inconvenient for a user of the system 102 associate or correlate entries from the events Journal with aberrations in the data included in a report. Thus, in some embodiments of the system 100, entries from the event journal and be displayed along with data in a report.

For example, FIG. 30 illustrates an example of her report including plots of the efficiency of a boiler identified as “Boiler 1” and the steam pressure of Boiler 1. In the illustrated example, the client report interface 115 is configured to indicate that an event journal entry has been associated with the date range of the data displayed in the report of FIG. 30. The interface 115 can be configured to indicate the existence of an event journal entry in any manner. In some embodiments, the interface 115 is configured to indicate the existence of an event journal entry by presenting a plot with a visual cue.

For example, as illustrated in FIG. 30, a bullet point 3000 is displayed along the horizontal axis of the plot illustrated in FIG. 30, aligned with the date and time associated with the event. This is merely one technique for creating a visual cue that can be used in the interface 115. Other techniques, such as color differentiations, bullet points, arrows, exclamation points, etc., can also be used.

Additionally, the interface 115 can be configured to display for the user, data representing the event corresponding to the visual cue in the portion 3000. For example, as shown in FIG. 30, a pop up 3002 is displayed near the bullet point 3000. The pop-up 3002 includes the text describing the event. For example, in some embodiments, the pop-up 3002 can include all of the text entered in the event description input 2606 described above with reference to FIG. 26. Optionally, the pop-up 3002 can include only a portion of, only a limited number of characters from, or a summary of the description input into the event description input 2606.

In some embodiments, as illustrated in FIG. 30, the pop-up 3002 can also include a command portion 3004 allowing a user to access a full view of the event description associated with the bullet point 3000. For example, upon activation of the command portion 3004, a full copy of the entire event description can be displayed. Optionally, the interface 115 can be configured to generate the pop-up 3002, or any other representation of the events associated with the bullet point 3000, when a user “mouse is over” the bullet point 3000. For example, as illustrated in FIG. 30, a cursor 3006 is illustrated as being adjacent to the bullet point 3000. This illustrates an example where the interface 115 has been configured to generate the pop-up 3002 when a user moves the cursor 3006 over or in the vicinity of the bullet point 3000.

In some embodiments, the interface number 115 can also be configured to display indications and/or portions of an event description on the other parts of the display, for example, in the area identified by reference 3008. Other techniques can also be used.

FIG. 31 illustrates another optional configuration for screen for viewing event entries. In the example of FIG. 31, a pop up screen 3100 including multiple journal entries is overlapped over a larger journal entry viewing window 3102. However, other configurations can also be used. Optionally, the interface 115 can be configured to allow event journals to be imported from other sources. For example, the “back end” of the event journal illustrated in FIGS. 30 and 31 can be in the form of commonly used database file formats, including for example but without limitation, comma-separated values (.csv), and other formats.

Another aspect of at least one of the embodiments disclosed herein includes the realization that when the interface 115 is programmed to provide alerts to one or more employees based on the occurrence of predetermined events, certain events causing alerts to be generated may occur more frequently. In some situations, a recipient of the alerts may find it annoying to receive an excessive number of alerts. Further, some recipients may prefer to block all alerts during certain predetermined times, such as, for example, earn your vacation or other times when the employee does not wish to receive such alerts.

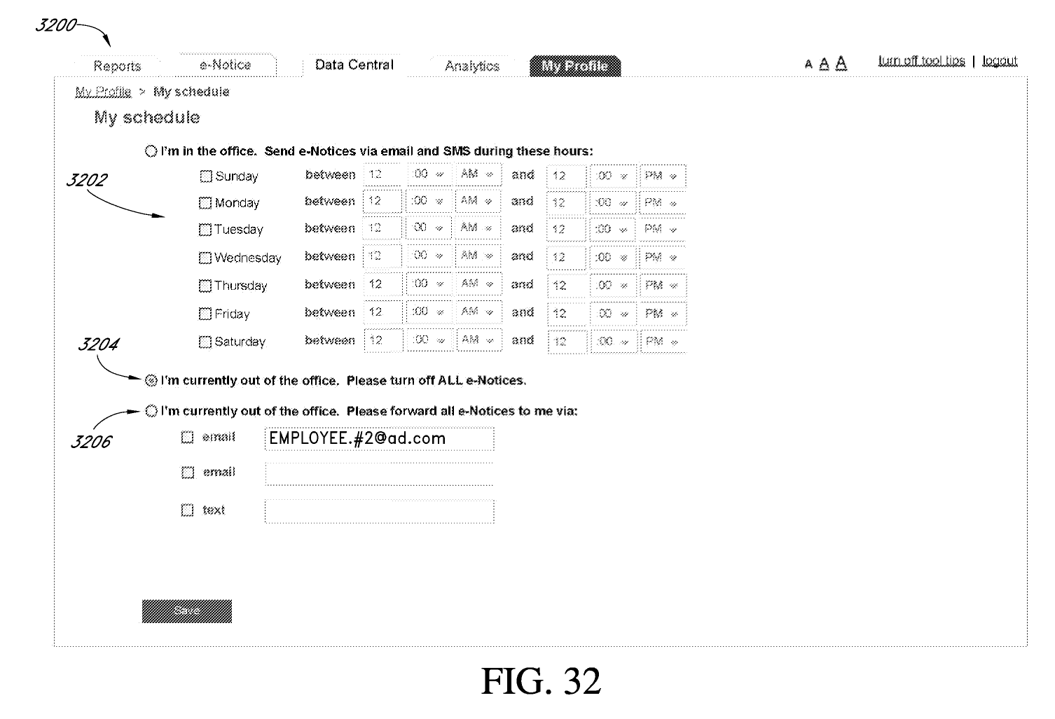

Thus, with reference to FIG. 32, the interface 115 can include an alert schedule interface 3200 configured to allow a user to restart the transmission of alerts. For example, in some embodiments, the interface 3200 can include a date restriction input 3202, a total alert block input 3204 and the forwarding input 3206, and/or other inputs.

The date restriction input 3202, and some embodiments, includes a plurality of fields arranged to allow a user to specify particular days in particular time ranges during those days in which during which the employee or user would like to receive alerts. As noted above with reference to the flowchart of FIG. 17A, such alerts can be delivered to the user by e-mail, text message, or any other technique.

The total alert block input 3204 can be configured to allow a user to block all alerts, also described as “e-Notices”. In the illustrated configuration, the input 3204 includes a simple radio button that can be “clicked” by a user operating the interface 115.

The forwarding input 3206 can be configured to allow a user to indicate that they are not currently in the office but to forward any alerts to one or more alternative e-mail addresses or text message addresses (i.e., phone numbers). Other configurations can also be used.

Although not illustrated in FIG. 32, the interface 115 cannot truly include, for example in the interface 3200, inputs allowing a user to “throttle” alerts transmitted to recipients. For example, the interface 3200 or another interface (not illustrated) can be configured to allow a user to limit the number or frequency of alerts transmitted or received by one or more users. This can be particularly useful in situations where an alert threshold has been set too close to a normally occurring value thereby generating an excessive number of alerts. In order to avoid overburdening a recipient with an excessive number of alerts, a throttling setting, as noted above, limiting the total number of alerts to a predetermined value for each day, week, month, etc. or limiting the frequency that alerts can be transmitted or received, can help prevent overburdening a user with an excessive number of alerts.

The foregoing disclosure has oftentimes partitioned devices and systems into multiple modules (e.g., components, computers, servers) for ease of explanation. It is to be understood, however, that one or more modules may operate as a single unit. Conversely, a single module may comprise one or more subcomponents that are distributed throughout one or more locations. Furthermore, the communication between the modules may occur in a variety of ways, such as hardware implementations (e.g., over a network, serial interface, parallel interface, or internal bus), software implementations (e.g., database passing variables), or a combination of hardware and software. Moreover, in some embodiments, the systems and methods described herein can advantageously be implemented using computer software, hardware, firmware, or any combination of software, hardware, and firmware.

The various features and processes described above can be used independently of one another, or can be combined in various ways. All possible combinations and subcombinations are intended to fall within the scope of this disclosure. Indeed, the novel methods and systems described herein can be embodied in a variety of other forms; furthermore, various omissions, substitutions, and changes in the form of the methods and systems described herein can be made without departing from the spirit of the disclosure. The accompanying claims and their equivalents are intended to cover such forms or modifications as would fall within the scope and spirit of the disclosure.

What is claimed is:

1. A method for optimizing power consumption of manufacturing facilities, the method comprising:
receiving a plurality of energy consumption and emission data from one or more energy consuming devices operating in a facility over a network;
transforming the plurality of data into a format that can be processed;
validating the plurality of data;
aggregating the plurality of data at a defined interval;
performing one or more analyses on the plurality of data using one or more computing devices; and
storing the results of the one or more analyses in computer storage.

2. The method of claim 1, wherein the step of performing one or more analyses on the plurality of data comprises performing analyses for a plurality of time resolutions.

3. The method of claim 1, further comprising automatically sending information over the network to control the one or more energy consumption sources.

4. The method of claim 3, wherein the control information reduces the energy use and environmental impact of the one or more energy consumption sources.

5. The method of claim 1, further comprising generating a report based on the result of the one or more analyses.

6. The method of claim 5, further comprising outputting the report to a user via a web-based user interface.

7. The method of claim 5, wherein generating a report comprises displaying the real-time status of the one or more of the energy consumption sources.

8. The method of claim 7, further comprising continuously updating the real-time status displayed at the defined interval.

9. The method of claim 5, wherein the report comprises a cumulative total value over a user-selected time interval.

10. The method of claim 5, wherein the report comprises a comparison of the value of one or more of the energy consumption sources over one or more time intervals.

11. The method of claim 5, wherein the report comprises electrical energy use by the one or more energy consumption sources.

12. The method of claim 5, wherein the report comprises natural gas use by the one or more energy consumption sources.

13. The method of claim 5, wherein the report comprises alternate fuel use by the one or more energy consumption sources.

14. The method of claim 5, wherein the report comprises water use by the one or more energy consumption sources.

15. The method of claim 5, wherein the report comprises wastewater discharge by the one or more energy consumption sources.

16. The method of claim 1, further comprising calculating a resource cost and emission output for the aggregated data.

17. The method of claim 1, further comprising generating an alert if the plurality of data satisfies a predefined alert condition.

18. The method of claim 17, wherein generating the alert comprises transmitting the alert via electronic mail to an address associated with the predefined alert condition.

19. The method of claim 17, wherein generating the alert comprises displaying the alert via the graphical user interface.

20. The method of claim 17, wherein generating the alert comprises displaying the alert via text message.

21. The method according to claim 17 additionally comprising blocking alerts from being displayed if a quantity of alerts exceeds a predetermined value.

22. The method of claim 1, wherein transforming the data into a format that can be processed comprises transforming the data into a database management format.

23. The method of claim 1, wherein validating the plurality of data comprises a filler process to fill in missing data and/or to replace invalid data.

24. The method according to claim 1 additionally comprising displaying a representation of at least a portion of the plurality of data on a user interface display, and displaying a representation of characteristics of an event occurring any time range of the portion of the plurality of data, wherein the characteristics represented are not contained in the data received during the receiving step.

25. The method according to claim 1 additionally comprising automatically repeating the step of performing at predetermined intervals and transmitting the results to a user following each predetermined interval.

26. A system for optimizing power consumption of manufacturing or production facilities, the system comprising:
one or more energy consuming devices;
a data acquisition device configured to receive data from the one or more energy consuming devices;
a computing device configured to poll the data acquisition device at a defined interval and receive sensor data corresponding to the defined interval, the computing device being configured to transform the data into a format that can be processed;
a remote server in communication with the computing device, the remote server configured to receive the formatted data corresponding to the defined interval over a network, the remote server comprising a computer memory that stores instructions for creating reports that describe energy usage and emissions output of the one or more energy consumption sensors and at least one processor that executes the stored instructions.

27. The system of claim 22, wherein the one or more energy consumption sources comprises a digital source.

28. The system of claim 22, wherein the one or more energy consumption sensors comprises an analog source.

29. The system of claim 22, wherein the data acquisition device comprises a programmable logic controller.

30. The system of claim 22, wherein the data acquisition device is further configured to output control signals for controlling the one or more energy consumption sources based on characteristics of the reports.

31. The system of claim 26, wherein the control signals reduce energy consumption and environmental impact of the one or more energy consumption sources.

32. The system of claim 22, wherein the remote server comprises a plurality of servers.

33. The system of claim 22, wherein the remote server is configured to output the reports to client computers over the network.

34. The system of claim 22, wherein the remote server further comprises one or more disk storage devices.

35. The system of claim 22, wherein the network is a secure virtual private network.

36. A method for monitoring energy consumption or waste emissions of a facility comprising:
monitoring a plurality of data representing energy consumption or waste emissions of a facility;
identifying a subset of the plurality of data; and
displaying the subset of the plurality of data on a display device in a scrolling configuration.

37. The method according to claim 32, additionally comprising determining a threshold value corresponding to a first of the plurality of data and changing an appearance of the display of the first data when the value of the first data crosses the threshold.

38. A method of determining carbon emissions from a facility comprising:
manufacturing a first product with a first energy consuming device;
determining energy usage of the first energy consuming device used for producing the first product;
transmitting first data representing the energy usage of the first energy consuming device are producing the first product to a first server;
further manufacturing the first product with a second energy consuming device;
determining energy usage of the second energy consuming device used for producing the first product;
transmitting second data representing the energy usage of the second energy consuming device used for producing the first product to the server
determining an amount of carbon emitted to produce the first product based on the determination of energy usage of the first energy consuming device and the determination of energy usage of the second energy consuming device;
transmitting third data representing the amount of carbon emitted from the server to a client device.

39. The method according to claim 34 additionally comprising transmitting the third data to the client device continuously.

40. The method according to claim 34 additionally comprising manufacturing a second product with the first energy consuming device, wherein the step of determining energy usage of the first energy consuming device used for producing the first product comprises apportioning a portion of the total energy usage of the first energy consuming device to the production of the first product.

41. A method of monitoring energy consumption or waste emissions from a facility, the method comprising:
operating a plurality of devices, each of the plurality of devices either consuming energy or emitting waste;
continuously detecting performance characteristics of each of the plurality of devices at a predetermined sampling rate;
transmitting data representing the performance characteristics of each of the plurality of devices to a server;
determining if the data transmitted to the server represents all of detected performance during the step of continuously detecting over a first predetermined limited amount of time;
storing an amount of the data corresponding the first predetermined limited amount of time in an area of a server reserved for data that has been verified as complete.

42. The method according to claim 37 wherein the predetermined sampling rate is at least one sample per second.

43. The method according to claim 37 wherein the first predetermined limited amount of time is at least 15 minutes.

44. A method of preparing data for analysis, comprising:
sampling output from at least one sensor at a first frequency;
storing data representing all of the output samples in the step of sampling;
storing a first subset of the data corresponding to first resolution lower than the data representing all of the output samples.

45. The method according to claim 40 additionally comprising storing a second subset of the data corresponding to a second resolution lower than the first resolution.

46. The method according to claim 40 additionally comprising receiving a request from a client device over a network for data sufficient to generate a plot of data representing output of the at least one sensor spanning a first period of time, determining whether to transmit all of the data representing all of the output samples in or the first subset of the data based on a magnitude of the first period of time.

47. The method according to claim 42 additionally comprising transmitting either all of the data representing all of the output samples or at the first subset of the data based on the result of the step of determining.

48. A method of alerting a user of a system for collecting data representing performance characteristics of a facility wherein the system is configured to allow the user to request the data, the method comprising:
sampling the output of the plurality of sensors of a facility;
storing data representing the output of the plurality of sensors;
transmitting the data to a client device over a network in response to a request for the data from a user operating the client device;
transmitting an electronic message to the user without receiving a request from the user if the data satisfies a predetermined condition determined by the user.

49. The method according to claim 44, wherein the step of transmitting an electronic message to the user comprises sending an e-mail to the user.

50. The method according to claim 44 additionally comprising in putting the predetermined condition to the client device.

51. The method according to claim 44, wherein the step of storing data comprises storing the data on a server.

52. The method according to claim 47 additionally comprising storing the predetermined condition on the server and analyzing the data to determine if the predetermined condition is satisfied by the data on the server.
